(19) United States
(12) Patent Application Publication
(10) Pub. No.: US 2026/0101805 A1
(43) Pub. Date: Apr. 9, 2026

(54) PACKAGE COMPRISING A STACK OF INTEGRATED DEVICES AND A PLURALITY OF WIRE BONDS

(71) Applicant: QUALCOMM Incorporated, San Diego, CA (US)

(72) Inventors: Yangyang SUN, San Diego, CA (US); Lily ZHAO, San Diego, CA (US); Periannan CHIDAMBARAM, San Diego, CA (US); Zhongze WANG, San Diego, CA (US); Jihong CHOI, San Diego, CA (US); Yujen CHEN, Taichung (TW)

(21) Appl. No.: 18/891,214

(22) Filed: Sep. 20, 2024

(51) Int. Cl. H01L 23/00; H01L 23/31; H01L 23/498; H01L 25/00; H01L 25/065

(52) U.S. Cl. CPC H10W 74/111; H10W 90/00; H10W 90/701; H10W 72/07354; H10W 72/07552; H10W 72/07553; H10W 72/347; H10W 72/521; H10W 72/531; H10W 72/884; H10W 90/732; H10W 90/754; H10W 90/756

(57) ABSTRACT

A package comprising a first integrated device; a second integrated device coupled to the first integrated device through an adhesive; a first plurality of wire bonds coupled to the first integrated device; a second plurality of wire bonds coupled to the second integrated device; an encapsulation layer at least partially encapsulating the first integrated device, the second integrated device, the first plurality of wire bonds and the second plurality of wire bonds; and a plurality of pillar interconnects.

### FIELD

Various features relate to packages with a stack of integrated devices.

### BACKGROUND

A package may include a substrate and integrated devices. These components are coupled together to provide a package that may perform various electrical functions. There is an ongoing need to provide better performing packages. Moreover, there is also an ongoing need to reduce and/or minimize the overall size of the packages.

### SUMMARY

Various features relate to packages with a stack of integrated devices.

One example provides a package comprising a first integrated device; a second integrated device coupled to the first integrated device through an adhesive; a first plurality of wire bonds coupled to the first integrated device; a second plurality of wire bonds coupled to the second integrated device; an encapsulation layer at least partially encapsulating the first integrated device, the second integrated device, the first plurality of wire bonds and the second plurality of wire bonds; and a plurality of pillar interconnects.

Another example provides a package comprising a first integrated device; a second integrated device coupled to the first integrated device through an adhesive; a first plurality of wire bonds coupled to the first integrated device; a second plurality of wire bonds coupled to the second integrated device; an encapsulation layer at least partially encapsulating the first integrated device, the second integrated device, the first plurality of wire bonds and the second plurality of wire bonds; a metallization portion coupled to the first plurality of wire bonds and the second plurality of wire bonds; and a plurality of pillar interconnects coupled to the metallization portion.

Another example provides a package comprising a metallization portion; a first integrated device coupled to the metallization portion through an adhesive; a first plurality of wire bonds coupled to the first integrated device and the metallization portion; a second integrated device coupled to the metallization portion through a first plurality of pillar interconnects and a first plurality of solder interconnects, wherein the second integrated device vertically overlaps with the first integrated device; and an encapsulation layer at least partially encapsulating the first integrated device and the second integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a stack of integrated devices and a plurality of wire bonds.

FIG. 2 illustrates an exemplary cross sectional plan view of a package that includes a stack of integrated devices and a plurality of wire bonds.

FIG. 3 illustrates an exemplary cross sectional plan view of a package that includes a stack of integrated devices and a plurality of wire bonds.

FIG. 4 illustrates an exemplary cross sectional profile view of a package that includes a metallization portion, a stack of integrated devices and a plurality of wire bonds.

FIGS. 5A-5D illustrate an exemplary sequence for fabricating a package that includes a stack of integrated devices and a plurality of wire bonds.

FIG. 6 illustrate an exemplary flow diagram of a method for fabricating a package that includes a stack of integrated devices and a plurality of wire bonds.

FIG. 7 illustrates an exemplary cross sectional profile view of a package that includes a metallization portion, a stack of integrated devices and a plurality of wire bonds.

FIGS. 8A-8D illustrate an exemplary sequence for fabricating a package that includes a stack of integrated devices and a plurality of wire bonds.

FIG. 9 illustrate an exemplary flow diagram of a method for fabricating a package that includes a stack of integrated devices and a plurality of wire bonds.

FIG. 10 illustrates an exemplary cross sectional profile view of a package that includes a metallization portion, a stack of integrated devices and a plurality of wire bonds.

FIG. 11 illustrates an exemplary cross sectional plan view of a package that includes a metallization portion, a stack of integrated devices and a plurality of wire bonds.

FIGS. 12A-12E illustrate an exemplary sequence for fabricating a package that includes a stack of integrated devices and a plurality of wire bonds.

FIG. 13 illustrate an exemplary flow diagram of a method for fabricating a package that includes a stack of integrated devices and a plurality of wire bonds.

FIGS. 14A-14B illustrate an exemplary sequence for fabricating a metallization portion.

FIG. 15 illustrates an exemplary flow chart of a method for fabricating a metallization portion.

FIG. 16 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a first integrated device; a second integrated device coupled to the first integrated device through an adhesive; a first plurality of wire bonds coupled to the first integrated device; a second plurality of wire bonds coupled to the second integrated device; an encapsulation layer at least partially encapsulating the first integrated device, the second integrated device, the first plurality of wire bonds and the second plurality of wire bonds; and a plurality of pillar interconnects. The use of the plurality of wire bonds may help reduce the pitch of interconnects of the package, since wire bonds have relatively thin diameters and high aspect ratios. This can help reduce the overall size and/or footprint of the package, while also providing high capacity bandwidth for the package.

### Exemplary Package Comprising a Stack of Integrated Devices and Wire Bonds

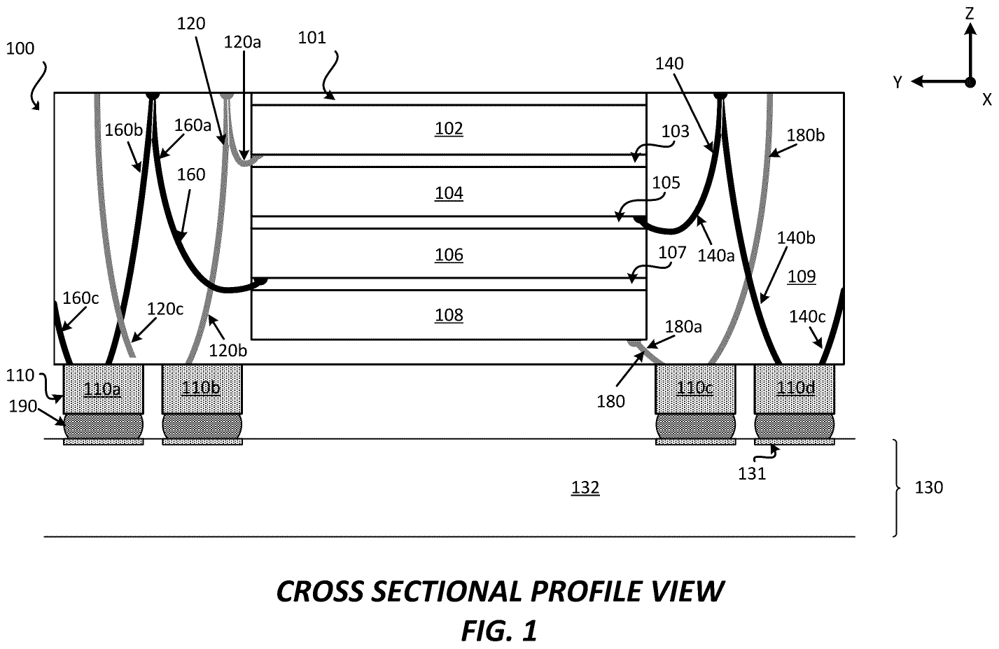

FIG. 1 illustrates a cross sectional profile view of a package 100 that includes a plurality of integrated devices and a plurality of wire bonds. The package 100 is coupled to a board 130 through a plurality of solder interconnects 190. The board 130 includes at least one board dielectric layer 132 and a plurality of board interconnects 131. The board 130 may include a printed circuit board (PCB). In some implementations, the package 100 may be coupled to a substrate (e.g., laminated substrate, coreless substrate, cored substrate) instead of the board 130.

The package 100 includes an integrated device 102, an integrated device 104, an integrated device 106, an integrated device 108, an adhesive 101, an adhesive 103, an adhesive 105, an adhesive 107, a plurality of wire bonds 120, a plurality of wire bonds 140, a plurality of wire bonds 160, a plurality of wire bonds 180, an encapsulation layer 109 and a plurality of pillar interconnects 110. The encapsulation layer 109 may at least partially encapsulate the integrated device 102, the integrated device 104, the integrated device 106, the integrated device 108, the adhesive 101, the adhesive 103, the adhesive 105, the adhesive 107, the plurality of wire bonds 120, the plurality of wire bonds 140, the plurality of wire bonds 160 and/or the plurality of wire bonds 180. The encapsulation layer 109 may include a mold, a resin, an epoxy and/or a filler. The plurality of pillar interconnects 110 may include a pillar interconnect 110a, a pillar interconnect 110b, a pillar interconnect 110c and a pillar interconnect 110d. The plurality of solder interconnects 190 may be coupled to the plurality of pillar interconnects 110.

The integrated device 102, the integrated device 104, the integrated device 106 and the integrated device 108 may be arranged as a stack of integrated devices (e.g., vertical stack of integrated devices). The integrated device 102, the integrated device 104, the integrated device 106 and/or the integrated device 108 may include a memory (e.g., memory chip). For example, one or more of the integrated device 102, the integrated device 104, the integrated device 106 and/or the integrated device 108 may be a memory device (e.g., memory chip, memory die). An adhesive 101 (e.g., die attach film (DAF), film over wire (FOW)) is coupled to the integrated device 102 (e.g., coupled to a back side of the integrated device 102). The integrated device 102 is coupled to the integrated device 104 through an adhesive 103 (e.g., die attach film, film over wire). The adhesive 103 is located between the integrated device 102 and the integrated device 104. The adhesive 103 is coupled to the integrated device 102 and the integrated device 104. The integrated device 104 is coupled to the integrated device 106 through an adhesive 105 (e.g., die attach film, film over wire). The adhesive 105 is located between the integrated device 104 and the integrated device 106. The adhesive 105 is coupled to the integrated device 104 and the integrated device 106. The integrated device 106 is coupled to the integrated device 108 through an adhesive 107 (e.g., die attach film, film over wire). The adhesive 107 is located between the integrated device 106 and the integrated device 108. The adhesive 107 is coupled to the integrated device 106 and the integrated device 108.

The plurality of wire bonds 120 are coupled to the integrated device 102 and at least one pillar interconnect (e.g., pillar interconnect 110b). The plurality of wire bonds 120 may include a wire bond 120a and a wire bond 120b. The wire bond 120a and the wire bond 120b may be considered as one wire bond or two separate wire bonds that are coupled to each other. There may be a ball bond between the wire bond 120a and the wire bond 120b. The ball bond may be considered part of the plurality of wire bonds 120. The wire bond 120a is coupled to the integrated device 102 (e.g., coupled to and touching a front side of the integrated device 102, coupled to and touching a pad of the integrated device 102). The wire bond 120a may be coupled to the front side of the integrated device 102 through a ball bond. The wire bond 120b is coupled to and touching the pillar interconnect 110b. An electrical path between the integrated device 102 and the board 130 may include the wire bond 120a, the wire bond 120b (may also include the ball bond between the wire bond 120a and the wire bond 120b), the pillar interconnect 110b, a solder interconnect from the plurality of solder interconnects 190 and a board interconnect from the plurality of board interconnects 131.

The plurality of wire bonds 140 are coupled to the integrated device 104 and at least one pillar interconnect (e.g., pillar interconnect 110d). The plurality of wire bonds 140 may include a wire bond 140a, a wire bond 140b and a wire bond 140c. The wire bond 140a and the wire bond 140b may be considered as one wire bond or two separate wire bonds that are coupled to each other. There may be a ball bond between the wire bond 140a and the wire bond 140b. The ball bond may be considered part of the plurality of wire bonds 140. The wire bond 140a is coupled to the integrated device 104 (e.g., coupled to and touching a front side of the integrated device 104, coupled to and touching a pad of the integrated device 104). The wire bond 140a may be coupled to the front side of the integrated device 104 through a ball bond. The wire bond 140b is coupled to and touching the pillar interconnect 110d. An electrical path between the integrated device 104 and the board 130 may include the wire bond 140a, the wire bond 140b (may also include the ball bond between the wire bond 140a and the wire bond 140b), the pillar interconnect 110d, a solder interconnect from the plurality of solder interconnects 190 and a board interconnect from the plurality of board interconnects 131. The wire bond 140c may or may not be coupled to the pillar interconnect 110d. For example, the wire bond 140c may or may not touch the pillar interconnect 110d. In some implementations, the wire bond 140c may be a dummy wire bond that is not electrically coupled to the integrated device 104.

The plurality of wire bonds 160 are coupled to the integrated device 106 and at least one pillar interconnect (e.g., pillar interconnect 110a). The plurality of wire bonds 160 may include a wire bond 160a, a wire bond 160b and a wire bond 160c. The wire bond 160a and the wire bond 160b may be considered as one wire bond or two separate wire bonds that are coupled to each other. There may be a ball bond between the wire bond 160a and the wire bond 160b. The ball bond may be considered part of the plurality of wire bonds 160. The wire bond 160a is coupled to the integrated device 106 (e.g., coupled to and touching a front side of the integrated device 106, coupled to and touching a pad of the integrated device 106). The wire bond 160a may be coupled to the front side of the integrated device 106 through a ball bond. The wire bond 160b is coupled to and touching the pillar interconnect 110a. An electrical path between the integrated device 106 and the board 130 may include the wire bond 160a, the wire bond 160b (may also include the ball bond between the wire bond 160a and the wire bond 160b), the pillar interconnect 110a, a solder interconnect from the plurality of solder interconnects 190 and a board interconnect from the plurality of board interconnects 131. The wire bond 160c may or may not be coupled to the pillar interconnect 110a. For example, the wire bond 160c may or may not touch the pillar interconnect 110a. In some implementations, the wire bond 160c may be a dummy wire bond that is not electrically coupled to the integrated device 106.

The plurality of wire bonds 180 are coupled to the integrated device 108 and at least one pillar interconnect (e.g., pillar interconnect 110c). The plurality of wire bonds 180 may include a wire bond 180a and a wire bond 180b. The wire bond 180a is coupled to the integrated device 108 (e.g., coupled to and touching a front side of the integrated device 108, coupled to and touching a pad of the integrated device 108). The wire bond 180a may be coupled to the front side of the integrated device 108 through a ball bond. The wire bond 180a is coupled to and touching the pillar interconnect 110c. An electrical path between the integrated device 108 and the board 130 may include the wire bond 180a, the pillar interconnect 110c, a solder interconnect from the plurality of solder interconnects 190 and a board interconnect from the plurality of board interconnects 131. The wire bond 180b may or may not be coupled to the pillar interconnect 110c. For example, the wire bond 180b may or may not touch the pillar interconnect 110c. In some implementations, the wire bond 180b may be a dummy wire bond that is not electrically coupled to the integrated device 108.

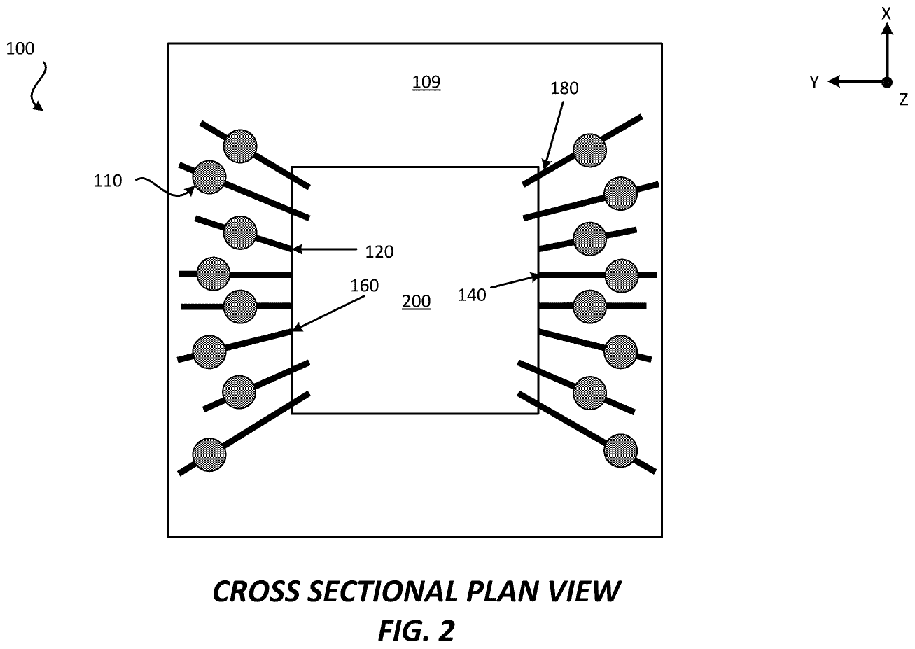

FIG. 2 illustrates a cross sectional plan view of the package 100. The package 100 includes a stack of integrated devices 200, the plurality of wire bonds 120, the plurality of wire bonds 140, the plurality of wire bonds 160, the plurality of wire bonds 180, the encapsulation layer 109 and the plurality of pillar interconnects 110. The plurality of pillar interconnects 110 are coupled to the plurality of wire bonds 120, the plurality of wire bonds 140, the plurality of wire bonds 160 and/or the plurality of wire bonds 180. It is noted that that in some implementations, the plurality of wire bonds 120, the plurality of wire bonds 140, the plurality of wire bonds 160 and/or the plurality of wire bonds 180 may be arranged in an intertwined configuration. The stack of integrated devices 200 may include the integrated device 102, the integrated device 104, the integrated device 106 and the integrated device 108. The stack of integrated devices 200 may also include the adhesive 101, the adhesive 103, the adhesive 105 and/or the adhesive 107. The stack of integrated devices 200 may be a vertical stack of integrated devices. In some implementations, the stack of integrated devices 200 may be arranged and/or configured such that (i) the front side of the integrated device 102 faces in the direction of the back side of the integrated device 104, (ii) the front side of the integrated device 104 faces in the direction of the back side of the integrated device 106, and/or (iii) the front side of the integrated device 106 faces in the direction of the back side of the integrated device 108. The stack of integrated devices 200 may include two or more integrated devices. Thus, in some implementations, the stack of integrated devices 200 may include less than four integrated devices or more than four integrated devices.

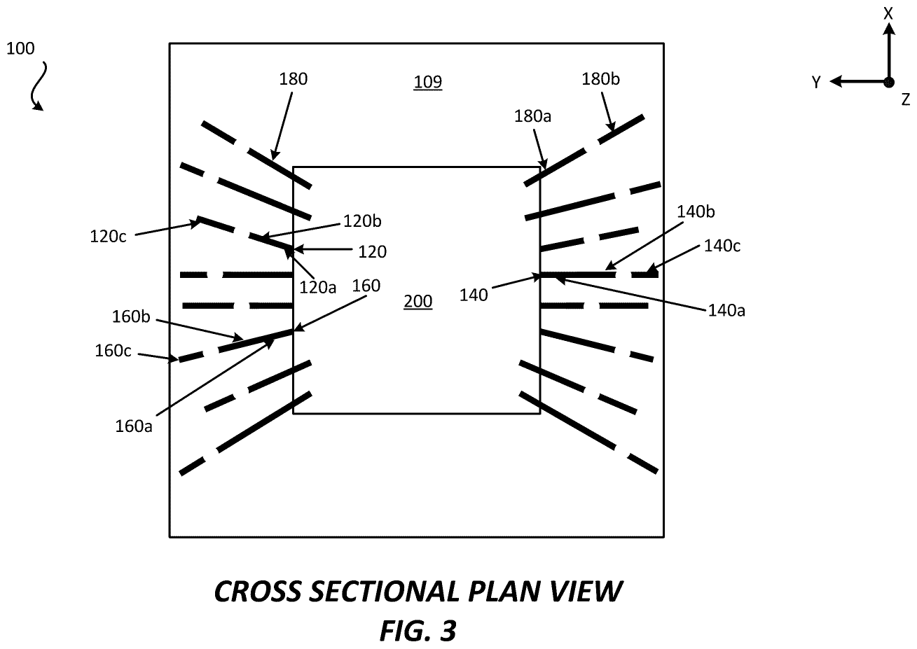

FIG. 3 illustrates a cross sectional plan view of the package 100. FIG. 3 is similar to FIG. 2, but does not illustrate the plurality of pillar interconnects 110. The package 100 of FIG. 3 includes a stack of integrated devices 200, the plurality of wire bonds 120, the plurality of wire bonds 140, the plurality of wire bonds 160, the plurality of wire bonds 180 and the encapsulation layer 109. FIG. 3 illustrates that there may be a separation of wire bonds. This may result in dummy wire bonds in the package 100. For example, the wire bond 180a may be separate from the wire bond 180b. The wire bond 120b may be separate from the wire bond 120c. The wire bond 140b may be separate from the wire bond 140c. The wire bond 160b may be separate from the wire bond 160c.

The plurality of wire bonds 120, the plurality of wire bonds 140, the plurality of wire bonds 160 and/or the plurality of wire bonds 180 may include wire bonds that touch opposite sides and/or surfaces of the encapsulation layer 109. The use of the plurality of wire bonds 120, the plurality of wire bonds 140, the plurality of wire bonds 160 and/or the plurality of wire bonds 180 may help reduce the pitch of interconnects of the package 100, since wire bonds have relatively thin diameters and high aspect ratios. This can help reduce the overall size and/or footprint of the package 100. Moreover, no through encapsulation layer vias or additional metallization interconnects may be necessary, which can help reduce the overall thickness of the package 100 and/or reduce the overall cost of the package 100. However, as will be further described below, in some implementations, metallization interconnects may be added and/or formed in the package.

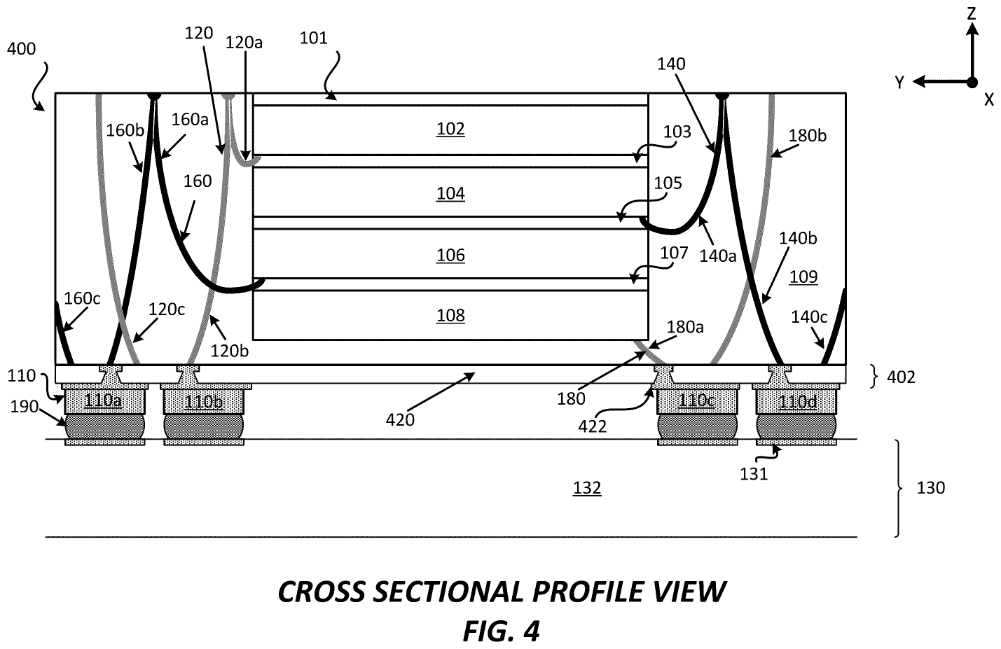

FIG. 4 illustrates a cross sectional profile view of a package 400 that includes a plurality of integrated devices, a plurality of wire bonds and a metallization portion 402. The package 400 is coupled to a board 130 through a plurality of solder interconnects 190. The board 130 includes at least one board dielectric layer 132 and a plurality of board interconnects 131. The board 130 may include a printed circuit board (PCB). In some implementations, the package 400 may be coupled to a substrate (e.g., laminated substrate, coreless substrate, cored substrate) instead of the board 130.

The package 400 is similar to the package 100, and also include a metallization portion 402. The description of the package 100 may also be applied to the package 400. The package 400 includes an integrated device 102, an integrated device 104, an integrated device 106, an integrated device 108, an adhesive 101, an adhesive 103, an adhesive 105, an adhesive 107, a plurality of wire bonds 120, a plurality of wire bonds 140, a plurality of wire bonds 160, a plurality of wire bonds 180, an encapsulation layer 109, the metallization portion 402 and a plurality of pillar interconnects 110. The encapsulation layer 109 may at least partially encapsulate the integrated device 102, the integrated device 104, the integrated device 106, the integrated device 108, the adhesive 101, the adhesive 103, the adhesive 105, the adhesive 107, the plurality of wire bonds 120, the plurality of wire bonds 140, the plurality of wire bonds 160, and the plurality of wire bonds 180. The encapsulation layer 109 may include a mold, a resin, an epoxy and/or a filler. The plurality of pillar interconnects 110 may include a pillar interconnect 110a, a pillar interconnect 110b, a pillar interconnect 110c and a pillar interconnect 110d. The plurality of solder interconnects 190 may be coupled to the plurality of pillar interconnects 110. The metallization portion 402 may include at least one dielectric layer 420 and a plurality of metallization interconnects 422.

The metallization portion 402 may be coupled to the encapsulation layer 109, the plurality of wire bonds 120, the plurality of wire bonds 140, the plurality of wire bonds 160 and the plurality of wire bonds 180. For example, the plurality of metallization interconnects 422 may be coupled to the plurality of wire bonds 120, the plurality of wire bonds 140, the plurality of wire bonds 160 and the plurality of wire bonds 180. In one example, the wire bond 120b may be coupled to and touching a metallization interconnect from the plurality of metallization interconnects 422. In one example, the wire bond 140b may be coupled to and touching a metallization interconnect from the plurality of metallization interconnects 422. In one example, the wire bond 160b may be coupled to and touching a metallization interconnect from the plurality of metallization interconnects 422. In one example, the wire bond 180a may be coupled to and touching a metallization interconnect from the plurality of metallization interconnects 422. The plurality of pillar interconnects 110 are coupled to the plurality of metallization interconnects 422.

In some implementations, an electrical path between the integrated device 102 and the board 130 may include the wire bond 120a, the wire bond 120b (may also include a ball bond between the wire bond 120a and the wire bond 120b), at least one metallization interconnect from the plurality of metallization interconnects 422, the pillar interconnect 110b, a solder interconnect from the plurality of solder interconnects 190 and a board interconnect from the plurality of board interconnects 131.

In some implementations, an electrical path between the integrated device 104 and the board 130 may include the wire bond 140a, the wire bond 140b (may also include a ball bond between the wire bond 140a and the wire bond 140b), at least one metallization interconnect from the plurality of metallization interconnects 422, the pillar interconnect 110d, a solder interconnect from the plurality of solder interconnects 190 and a board interconnect from the plurality of board interconnects 131.

In some implementations, an electrical path between the integrated device 106 and the board 130 may include the wire bond 160a, the wire bond 160b (may also include a ball bond between the wire bond 160a and the wire bond 160b), at least one metallization interconnect from the plurality of metallization interconnects 422, the pillar interconnect 110a, a solder interconnect from the plurality of solder interconnects 190 and a board interconnect from the plurality of board interconnects 131.

In some implementations, an electrical path between the integrated device 108 and the board 130 may include the wire bond 180a, at least one metallization interconnect from the plurality of metallization interconnects 422, the pillar interconnect 110c, a solder interconnect from the plurality of solder interconnects 190 and a board interconnect from the plurality of board interconnects 131.

The metallization portion 402 may include a redistribution portion. The plurality of metallization interconnects 422 may include a plurality of redistribution interconnects. A redistribution interconnect may include portions that have a U-shape or V-shape. The terms “U-shape” and” V-shape” shall be interchangeable. The terms “U-shape” and “V-shape” may refer to the side profile shape of the interconnects, metallization interconnects and/or redistribution interconnects. The U-shape interconnect (e.g., U-shape side profile interconnect) and the V-shape interconnect (e.g., V-shape side profile interconnect) may have a top portion and a bottom portion. A bottom portion of a U-shape interconnect (or a V-shape interconnect) may be coupled to a top portion of another U-shape interconnect (or a V-shape interconnect). In some implementations, a process for fabricating redistribution interconnects may form the U-shape interconnect (or the V-shape interconnect).

An integrated device (e.g., 102) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 102) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 400) may be implemented in a radio frequency (RF) package. The RF package may be a radio frequency front end (RFFE) package. A package (e.g., 100, 400) may be configured to provide Wireless Fidelity (WiFi) communication and/or cellular communication (e.g., 2G, 3G, 4G, 5G). The packages (e.g., 100, 400) may be configured to support Global System for Mobile (GSM) Communications, Universal Mobile Telecommunications System (UMTS), and/or Long-Term Evolution (LTE). The packages (e.g., 100, 400) may be configured to transmit and receive signals having different frequencies and/or communication protocols.

### Exemplary Sequence for Fabricating a Package Comprising a Stack of Integrated Devices and Wire Bonds

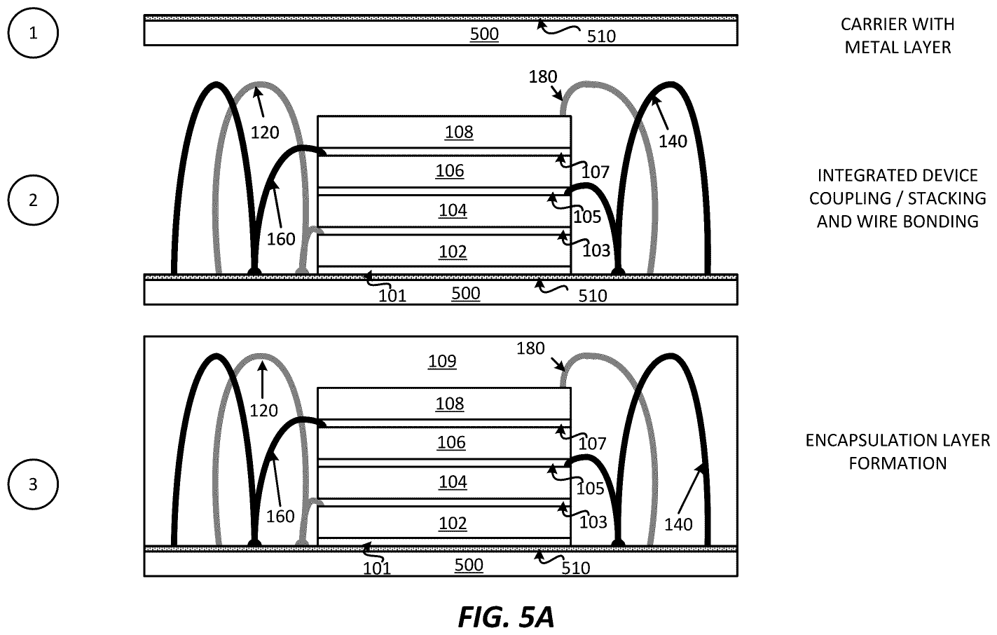

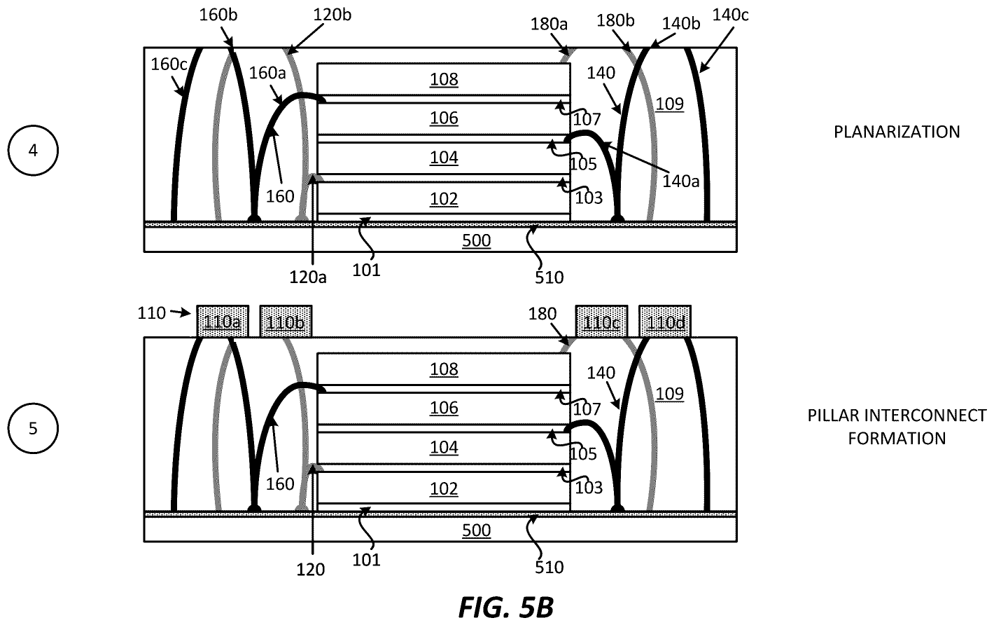

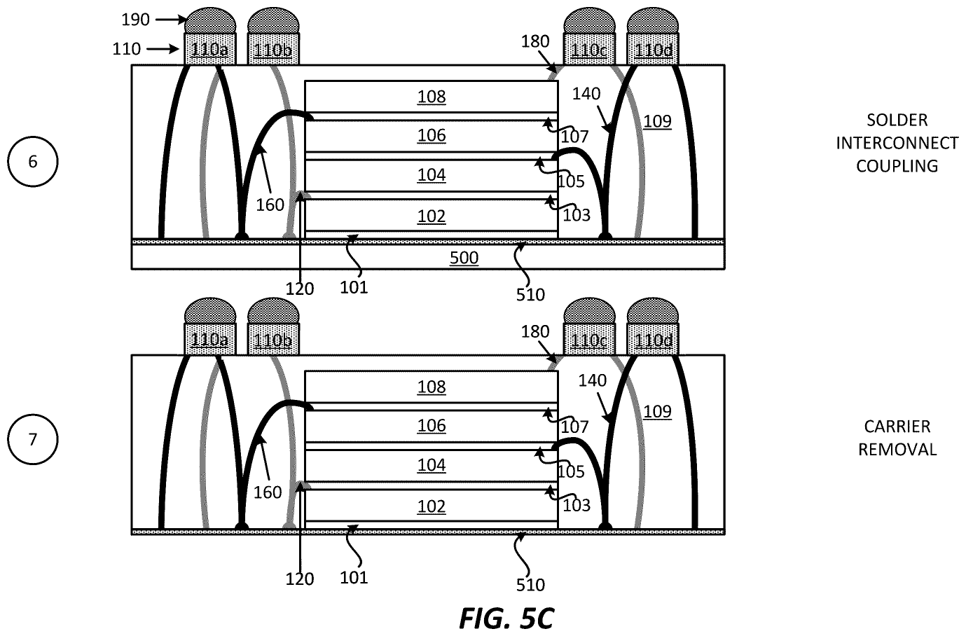

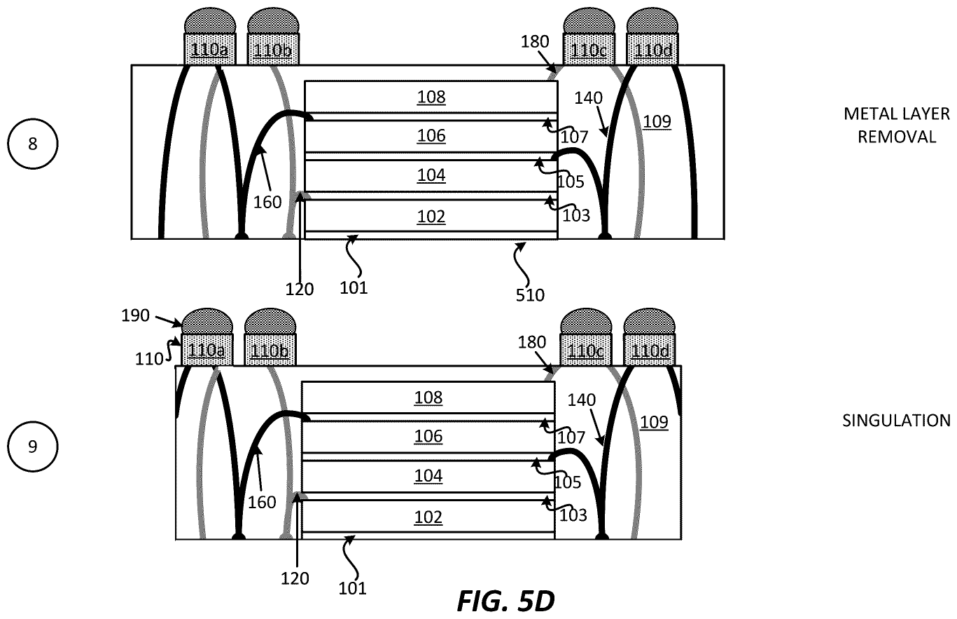

In some implementations, fabricating a package includes several processes. FIGS. 5A-5D illustrate an exemplary sequence for providing or fabricating a package. In some implementations, the sequence of FIGS. 5A-5D may be used to provide or fabricate the package 100. However, the process of FIGS. 5A-5D may be used to fabricate any of the packages described in the disclosure.

It should be noted that the sequence of FIGS. 5A-5D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 5A, illustrates a state after a carrier 500 and a metal layer 510 are provided. The carrier 500 may include glass or silicon. Different implementations may use different materials for the carrier 500. The metal layer 510 may be formed on the carrier 500 through a sputtering process. The metal layer 510 may include a seed layer.

Stage 2 illustrates a state after (i) a plurality of integrated devices are coupled to the carrier 500 and the metal layer 510 and (ii) a plurality of wire bonds are coupled to the integrated devices and the metal layer 510. The plurality of wire bonds may include a plurality of ball bonds. Below is an example of a sequence for coupling integrated devices and forming a plurality of wire bonds.

In one example, the integrated device 102 may be coupled to the metal layer 510 through the adhesive 101. A back side of the integrated device 102 may be coupled to the metal layer 510 through the adhesive 101. A plurality of wire bonds 120 may be formed and coupled to the integrated device 102 and the metal layer 510 through a wire bonding process. The plurality of wire bonds 120 may be coupled to pads of the front side of the integrated device 102. The plurality of wire bonds 120 may be formed from the integrated device 102 to a first portion of the metal layer 510 and then to a second portion of the metal layer 510. In some implementations, the plurality of wire bonds 120 may be formed from a second portion of the metal layer 510 to a first portion of the metal layer 510 and then to the integrated device 102.

Next, the integrated device 104 may be coupled to the integrated device 102 through the adhesive 103. For example, the backside of the integrated device 104 may be coupled to the front side of the integrated device 102 through the adhesive 103. The adhesive 103 may encapsulate part of the plurality of wire bonds 120 located between the integrated device 102 and the integrated device 104. A plurality of wire bonds 140 may be formed and coupled to the integrated device 104 and the metal layer 510 through a wire bonding process. The plurality of wire bonds 140 may be coupled to pads of the front side of the integrated device 104. The plurality of wire bonds 140 may be formed from the integrated device 104 to a portion of the metal layer 510 and then to another portion of the metal layer 510. In some implementations, the plurality of wire bonds 140 may be formed from a portion of the metal layer 510 to another portion of the metal layer 510 and then to the integrated device 104.

Next, the integrated device 106 may be coupled to the integrated device 104 through the adhesive 105. For example, the backside of the integrated device 106 may be coupled to the front side of the integrated device 104 through the adhesive 105. The adhesive 105 may encapsulate part of the plurality of wire bonds 140 located between the integrated device 104 and the integrated device 106. A plurality of wire bonds 160 may be formed and coupled to the integrated device 106 and the metal layer 510 through a wire bonding process. The plurality of wire bonds 160 may be coupled to pads of the front side of the integrated device 106. The plurality of wire bonds 160 may be formed from the integrated device 106 to a portion of the metal layer 510 and then to another portion of the metal layer 510. In some implementations, the plurality of wire bonds 160 may be formed from a portion of the metal layer 510 to another portion of the metal layer 510 and then to the integrated device 106.

Next, the integrated device 108 may be coupled to the integrated device 106 through the adhesive 107. For example, the backside of the integrated device 108 may be coupled to the front side of the integrated device 106 through the adhesive 107. The adhesive 107 may encapsulate part of the plurality of wire bonds 160 located between the integrated device 106 and the integrated device 108. A plurality of wire bonds 180 may be formed and coupled to the integrated device 108 and the metal layer 510 through a wire bonding process. The plurality of wire bonds 180 may be coupled to pads of the front side of the integrated device 108. The plurality of wire bonds 180 may be formed from the integrated device 108 to a portion of the metal layer 510. In some implementations, the plurality of wire bonds 180 may be formed from a portion of the metal layer 510 to the integrated device 108.

The above is merely an example of a sequence of coupling integrated devices and forming a plurality of wire bonds. Different implementations may have different sequences for coupling integrated devices and forming the plurality of wire bonds. Stage 2 illustrates a vertical stack of integrated devices (e.g., 200) and a plurality of wire bonds. The vertical stack of integrated devices may have offset integrated device(s) (e.g., horizontally offset integrated devices).

Stage 3 illustrates a state after an encapsulation layer 109 is provided and coupled to the carrier 500 and the metal layer 510. The encapsulation layer 109 may at least partially encapsulate the integrated device 102, the integrated device 104, the integrated device 106, the integrated device 108, the adhesive 101, the adhesive 103, the adhesive 105, the adhesive 107, the plurality of wire bonds 120, the plurality of wire bonds 140, the plurality of wire bonds 160 and/or the plurality of wire bonds 180. The encapsulation layer 109 may include a mold, a resin, an epoxy and/or a filler. The encapsulation layer 109 may be provided by using a compression and transfer molding process, a sheet molding process, or a liquid molding process. The encapsulation layer 109 may be over molded.

Stage 4, as shown in FIG. 5B, illustrates a state after a planarization process of the encapsulation layer 109. A portion of the encapsulation layer 109, a portion of the plurality of wire bonds 120, a portion of the plurality of wire bonds 140, a portion of the plurality of wire bonds 160 and/or a portion of the plurality of wire bonds 180 may be removed and/or grinded off. The planarization process may separate and/or form wire bonds into several wire bonds. For example, after planarization, a wire bond 180a and a wire bond 180b may be defined from the plurality of wire bonds 180. Similar other separate wire bonds may also be formed from the plurality of wire bonds 120, the plurality of wire bonds 140 and/or the plurality of wire bonds 160.

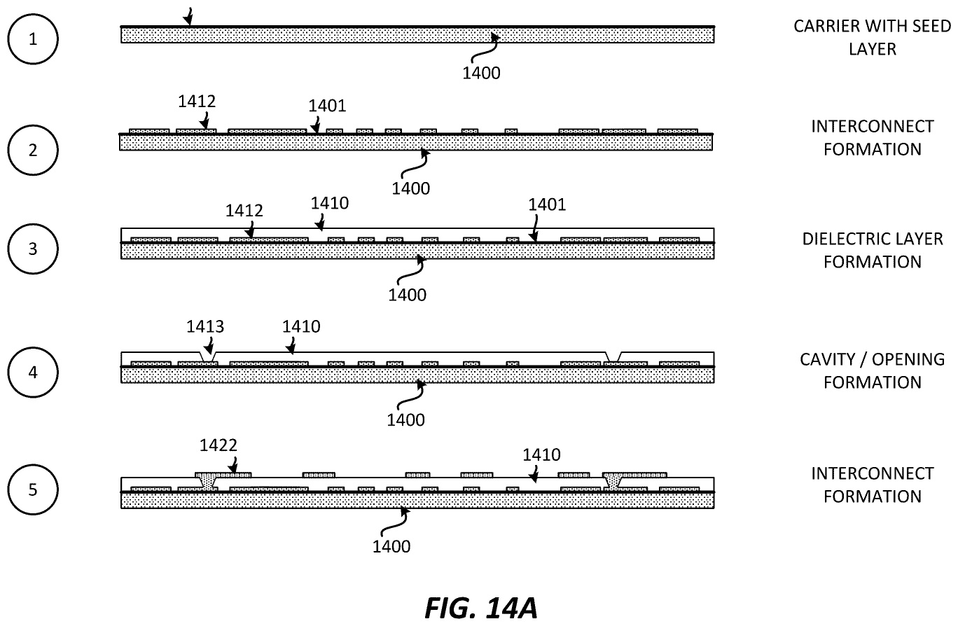

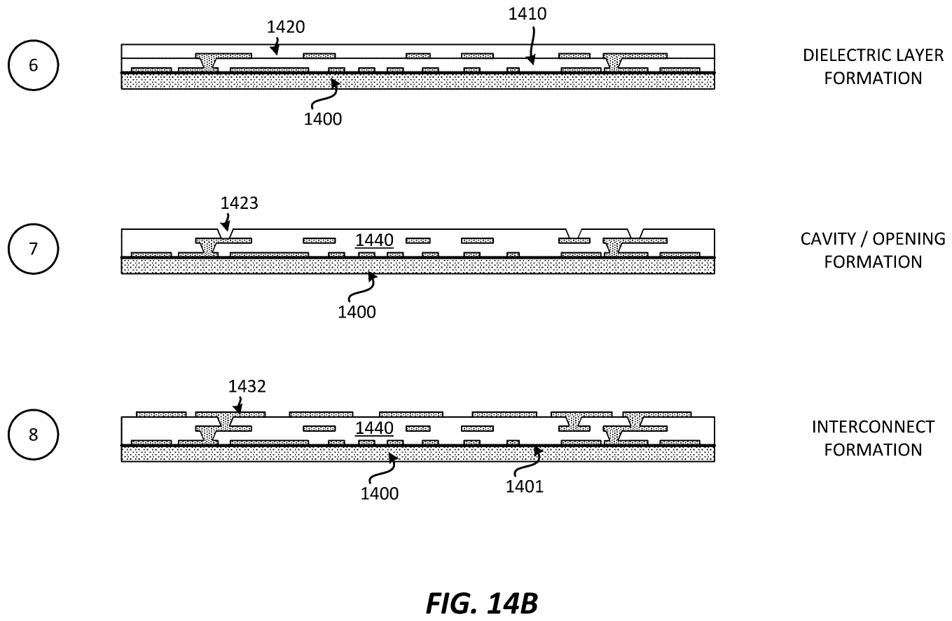

In some implementations, a metallization portion (e.g., 402) may be formed and coupled to the encapsulation layer 109 and the plurality of wire bonds. The metallization portion 402 may include at least one dielectric layer 420 and a plurality of metallization interconnects 422. The plurality of metallization interconnects 422 may be formed and coupled to the plurality of wire bonds (e.g., 120, 140, 160, 180). In some implementations, a deposition process, a lamination process, an etching process (e.g., photo etching process), a laser process, an exposure process, a development process, a lithography process, a plating process, and/or a strip process may be used to form the metallization portion 402. An example of forming a metallization portion is illustrated and described below in at least FIGS. 14A-14B.

Stage 5 illustrates a state after a plurality of pillar interconnects 110 are formed. The plurality of pillar interconnects 110 may be formed and coupled to the plurality of wire bonds (e.g., 120, 140, 160, 180). A plating process may be used to form the plurality of pillar interconnects 110. If a metallization portion was previously formed, the plurality of pillar interconnects 110 may be formed and coupled to the metallization portion (e.g., 402). The plurality of pillar interconnects 110 may be coupled to the plurality of metallization interconnects 422 of the metallization portion 402.

Stage 6 of FIG. 5C, illustrates a state after a plurality of solder interconnects 190 are coupled to the plurality of pillar interconnects 110. A solder reflow process may be used to couple the plurality of solder interconnects 190 to the plurality of pillar interconnects 110.

Stage 7 illustrates a state after the carrier 500 is detached from the metal layer 510. The carrier 500 may be detached or grinded off from the metal layer 510.

Stage 8, as shown in FIG. 5D, illustrates a state after the metal layer 510 is removed. The metal layer 510 may be grinded off.

Stage 9 illustrates a state after singulation to form individual packages (e.g., 100) that includes a stack of integrated devices, a plurality of wire bonds, an encapsulation layer and a plurality of pillar interconnects. A saw process may be used for the singulation process. The singulation process may remove some wire bonds from the plurality of wire bonds. For example, some wire bonds from the plurality of wire bonds 140 and/or from the plurality of wire bonds 160 may be removed.

### Exemplary Flow Diagram of a Method for Fabricating a Package Comprising a Stack of Integrated Devices and Wire Bonds

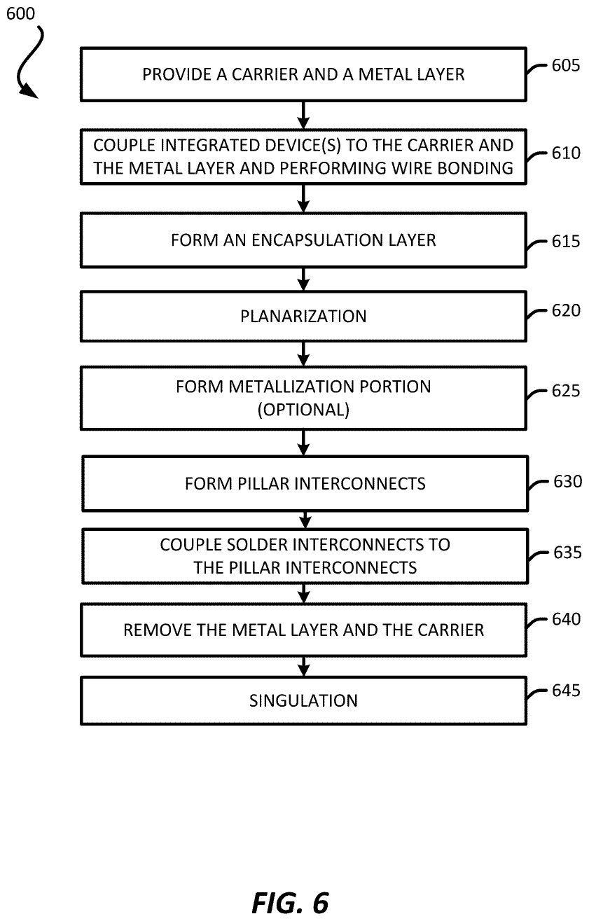

In some implementations, fabricating a package includes several processes. FIG. 6 illustrates an exemplary flow diagram of a method 600 for providing or fabricating a package. In some implementations, the method 600 of FIG. 6 may be used to provide or fabricate the package 100 and/or the package 400 described in the disclosure. However, the method 600 may be used to provide or fabricate any of the packages described in the disclosure.

It should be noted that the method 600 of FIG. 6 may combine one or more processes in order to simplify and/or clarify the method for providing or fabricating a package. In some implementations, the order of the processes may be changed or modified.

The method provides (at 605) a carrier and a metal layer. Stage 1 of FIG. 5A, illustrates and describes an example of a state after a carrier 500 and a metal layer 510 are provided. The carrier 500 may include glass or silicon. Different implementations may use different materials for the carrier 500. The metal layer 510 may be formed on the carrier 500 through a sputtering process. The metal layer 510 may include a seed layer.

The method couples (at 610) a plurality of integrated devices and forms (at 610) a plurality of wire bonds through one or more wire bonding processes. Stage 2 of FIG. 5A, illustrates and describes an example of a state after (i) a plurality of integrated devices are coupled to the carrier 500 and the metal layer 510 and (ii) a plurality of wire bonds are coupled to the integrated devices and the metal layer 510. The plurality of wire bonds may include a plurality of ball bonds. Below is an example of a sequence for coupling integrated devices and forming a plurality of wire bonds.

In one example, the integrated device 102 may be coupled to the metal layer 510 through the adhesive 101. A back side of the integrated device 102 may be coupled to the metal layer 510 through the adhesive 101. A plurality of wire bonds 120 may be formed and coupled to the integrated device 102 and the metal layer 510 through a wire bonding process. The plurality of wire bonds 120 may be coupled to pads of the front side of the integrated device 102. The plurality of wire bonds 120 may be formed from the integrated device 102 to a first portion of the metal layer 510 and then to a second portion of the metal layer 510. In some implementations, the plurality of wire bonds 120 may be formed from a second portion of the metal layer 510 to a first portion of the metal layer 510 and then to the integrated device 102.

Next, the integrated device 104 may be coupled to the integrated device 102 through the adhesive 103. For example, the backside of the integrated device 104 may be coupled to the front side of the integrated device 102 through the adhesive 103. The adhesive 103 may encapsulate part of the plurality of wire bonds 120 located between the integrated device 102 and the integrated device 104. A plurality of wire bonds 140 may be formed and coupled to the integrated device 104 and the metal layer 510 through a wire bonding process. The plurality of wire bonds 140 may be coupled to pads of the front side of the integrated device 104. The plurality of wire bonds 140 may be formed from the integrated device 104 to a portion of the metal layer 510 and then to another portion of the metal layer 510. In some implementations, the plurality of wire bonds 140 may be formed from a portion of the metal layer 510 to another portion of the metal layer 510 and then to the integrated device 104.

Next, the integrated device 106 may be coupled to the integrated device 104 through the adhesive 105. For example, the backside of the integrated device 106 may be coupled to the front side of the integrated device 104 through the adhesive 105. The adhesive 105 may encapsulate part of the plurality of wire bonds 140 located between the integrated device 104 and the integrated device 106. A plurality of wire bonds 160 may be formed and coupled to the integrated device 106 and the metal layer 510 through a wire bonding process. The plurality of wire bonds 160 may be coupled to pads of the front side of the integrated device 106. The plurality of wire bonds 160 may be formed from the integrated device 106 to a portion of the metal layer 510 and then to another portion of the metal layer 510. In some implementations, the plurality of wire bonds 160 may be formed from a portion of the metal layer 510 to another portion of the metal layer 510 and then to the integrated device 106.

Next, the integrated device 108 may be coupled to the integrated device 106 through the adhesive 107. For example, the backside of the integrated device 108 may be coupled to the front side of the integrated device 106 through the adhesive 107. The adhesive 107 may encapsulate part of the plurality of wire bonds 160 located between the integrated device 106 and the integrated device 108. A plurality of wire bonds 180 may be formed and coupled to the integrated device 108 and the metal layer 510 through a wire bonding process. The plurality of wire bonds 180 may be coupled to pads of the front side of the integrated device 108. The plurality of wire bonds 180 may be formed from the integrated device 108 to a portion of the metal layer 510. In some implementations, the plurality of wire bonds 180 may be formed from a portion of the metal layer 510 to the integrated device 108.

The above is merely an example of a sequence of coupling integrated devices and forming a plurality of wire bonds. Different implementations may have different sequences for coupling integrated devices and forming the plurality of wire bonds.

The method forms (at 615) an encapsulation layer. Stage 3 of FIG. 5A, illustrates and describes an example of a state after an encapsulation layer 109 is provided and coupled to the carrier 500 and the metal layer 510. The encapsulation layer 109 may at least partially encapsulate the integrated device 102, the integrated device 104, the integrated device 106, the integrated device 108, the adhesive 101, the adhesive 103, the adhesive 105, the adhesive 107, the plurality of wire bonds 120, the plurality of wire bonds 140, the plurality of wire bonds 160 and/or the plurality of wire bonds 180. The encapsulation layer 109 may include a mold, a resin, an epoxy and/or a filler. The encapsulation layer 109 may be provided by using a compression and transfer molding process, a sheet molding process, or a liquid molding process. The encapsulation layer 109 may be over molded.

The method performs (at 620) a planarization process on the encapsulation layer. Stage 4 of FIG. 5B, illustrates and describes an example of a state after a planarization process of the encapsulation layer 109. A portion of the encapsulation layer 109, a portion of the plurality of wire bonds 120, a portion of the plurality of wire bonds 140, a portion of the plurality of wire bonds 160 and/or a portion of the plurality of wire bonds 180 may be removed and/or grinded off. The planarization process may separate wire bonds into several wire bonds. For example, after planarization, a wire bond 180a and a wire bond 180b may be defined from the plurality of wire bonds 180. Similar other separate wire bonds may also be formed from the plurality of wire bonds 120, the plurality of wire bonds 140 and/or the plurality of wire bonds 160.

The method may optionally form (at 625) a metallization portion. A metallization portion (e.g., 402) may be formed and coupled to the encapsulation layer 109 and the plurality of wire bonds (e.g., 120, 140, 160, 180). The metallization portion may include at least one dielectric layer 420 and a plurality of metallization interconnects 422. In some implementations, a deposition process, a lamination process, an etching process (e.g., photo etching process), a laser process, an exposure process, a development process, a lithography process, a plating process, and/or a strip process may be used to form the metallization portion 402. An example of forming a metallization portion is illustrated and described below in at least FIGS. 14A-14B.

The method forms (at 630) a plurality of pillar interconnects. The plurality of pillar interconnects may be formed and coupled to the plurality of wire bonds. In some implementations, the plurality of pillar interconnects may be formed and coupled to the plurality of metallization interconnects of the metallization portion. Stage 5 of FIG. 5B, illustrates and describes an example of a state after a plurality of pillar interconnects 110 are formed. The plurality of pillar interconnects 110 may be formed and coupled to the plurality of wire bonds (e.g., 120, 140, 160, 180). A plating process may be used to form the plurality of pillar interconnects 110. If a metallization portion was previously formed, the plurality of pillar interconnects 110 may be formed and coupled to the metallization portion (e.g., 402). The plurality of pillar interconnects 110 may be coupled to the plurality of metallization interconnects 422 of the metallization portion 402.

The method forms and couples (at 635) a plurality of solder interconnects to the plurality of pillar interconnects. Stage 6 of FIG. 5C, illustrates and describes an example of a state after a plurality of solder interconnects 190 are coupled to the plurality of pillar interconnects 110. A solder reflow process may be used to couple the plurality of solder interconnects 190 to the plurality of pillar interconnects 110.

The method removes (at 640) the carrier and the metal layer. Stage 7 of FIG. 5C, illustrates and describes an example of a state after the carrier 500 is detached from the metal layer 510. The carrier 500 may be detached or grinded off from the metal layer 510. Stage 8 of FIG. 5D, illustrates and describes an example of a state after the metal layer 510 is removed. The metal layer 510 may be grinded off.

The method singulates (at 645) to form a package (e.g., 100, 400) that includes a stack of integrated devices (e.g., 200), a plurality of wire bonds (e.g., 120, 140, 160, 180), an encapsulation layer (e.g., 109) and a plurality of pillar interconnects (e.g., 110). Stage 9 of FIG. 5D, illustrates and describes an example of a state after singulation to form individual packages (e.g., 100) that includes a stack of integrated devices, a plurality of wire bonds, an encapsulation layer and a plurality of pillar interconnects. A saw process may be used for the singulation process. The singulation process may remove some wire bonds from the plurality of wire bonds. For example, some wire bonds from the plurality of wire bonds 140 and/or from the plurality of wire bonds 160 may be removed.

### Exemplary Package Comprising a Stack of Integrated Devices and Wire Bonds

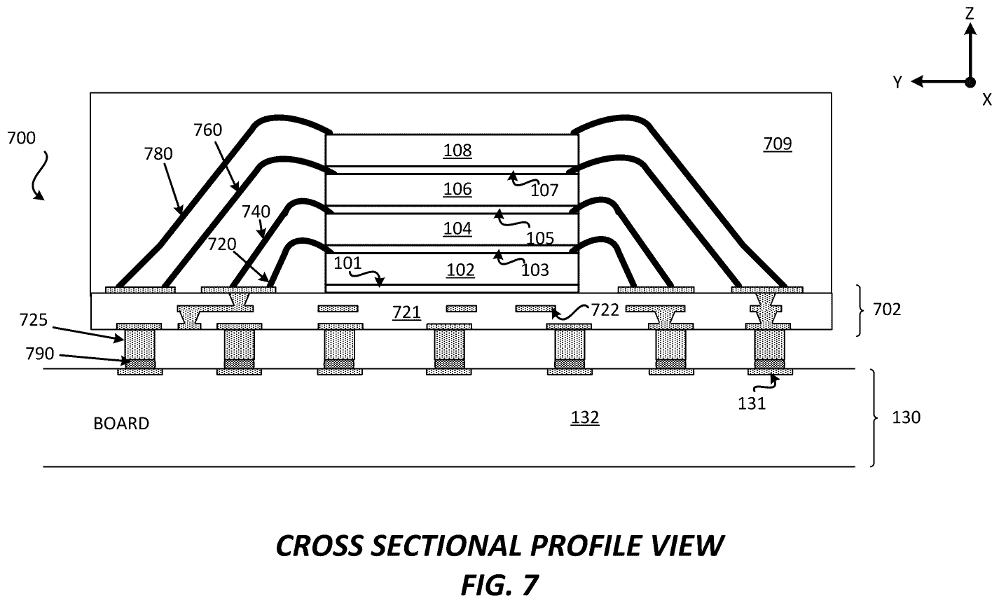

FIG. 7 illustrates a cross sectional profile view of a package 700 that includes a plurality of integrated devices, a plurality of wire bonds and a metallization portion. The package 700 is coupled to a board 130 through a plurality of solder interconnects 790. The board 130 includes at least one board dielectric layer 132 and a plurality of board interconnects 131. The board 130 may include a printed circuit board (PCB). In some implementations, the package 700 may be coupled to a substrate (e.g., laminated substrate, coreless substrate, cored substrate) instead of the board 130.

The package 700 includes an integrated device 102, an integrated device 104, an integrated device 106, an integrated device 108, an adhesive 101, an adhesive 103, an adhesive 105, an adhesive 107, a plurality of wire bonds 720, a plurality of wire bonds 740, a plurality of wire bonds 760, a plurality of wire bonds 780, an encapsulation layer 109, the metallization portion 702 and a plurality of pillar interconnects 725. The encapsulation layer 109 may at least partially encapsulate the integrated device 102, the integrated device 104, the integrated device 106, the integrated device 108, the adhesive 101, the adhesive 103, the adhesive 105, the adhesive 107, the plurality of wire bonds 720, the plurality of wire bonds 740, the plurality of wire bonds 760, and the plurality of wire bonds 780. The encapsulation layer 109 may include a mold, a resin, an epoxy and/or a filler. The plurality of pillar interconnects 725 may include a pillar interconnect 725a, a pillar interconnect 725b, a pillar interconnect 725c and a pillar interconnect 725d. The plurality of solder interconnects 790 may be coupled to the plurality of pillar interconnects 725. The metallization portion 702 may include at least one dielectric layer 721 and a plurality of metallization interconnects 722.

The integrated device 102, the integrated device 104, the integrated device 106 and the integrated device 108 may be arranged as a stack of integrated devices (e.g., vertical stack of integrated devices). The vertical stack of integrated devices may include integrated device(s) that are offset (e.g., horizontally offset). Different implementations may have a different number of integrated devices. A stack of integrated devices may have two or more integrated devices. The integrated device 102, the integrated device 104, the integrated device 106 and/or the integrated device 108 may include a memory (e.g., memory chip). For example, one or more of the integrated device 102, the integrated device 104, the integrated device 106 and/or the integrated device 108 may be a memory device (e.g., memory chip, memory die). An adhesive 101 (e.g., die attach film (DAF), film over wire (FOW)) is coupled to the integrated device 102. A front side of the integrated device 102 may be coupled to a back side of the integrated device 104 through an adhesive 103 (e.g., die attach film, film over wire). The adhesive 103 is located between the integrated device 102 and the integrated device 104. The adhesive 103 is coupled to the integrated device 102 and the integrated device 104. A front side of the integrated device 104 may be coupled to a back side of the integrated device 106 through an adhesive 105 (e.g., die attach film, film over wire). The adhesive 105 is located between the integrated device 104 and the integrated device 106. The adhesive 105 is coupled to the integrated device 104 and the integrated device 106. A front side of the integrated device 106 may be coupled to a back side of the integrated device 108 through an adhesive 107 (e.g., die attach film, film over wire). The adhesive 107 is located between the integrated device 106 and the integrated device 108. The adhesive 107 is coupled to the integrated device 106 and the integrated device 108. The back side of the integrated device 102 is coupled to the metallization portion 702 through the adhesive 101.

The plurality of wire bonds 720 are coupled to the integrated device 102 and at least one metallization interconnect from the plurality of metallization interconnects 722 of the metallization portion 702. The plurality of wire bonds 720 may include a plurality of ball bonds. The plurality of wire bonds 720 may be coupled to and touching a front side of the integrated device 102. The plurality of wire bonds 720 may be coupled to and touching metallization interconnect(s) from the plurality of metallization interconnects 722. An electrical path between the integrated device 102 and the board 130 may include the plurality of wire bonds 720, at least one metallization interconnects from the plurality of metallization interconnects 722, at least one pillar interconnects 725 from the plurality of pillar interconnects 725, a solder interconnect from the plurality of solder interconnects 790 and a board interconnect from the plurality of board interconnects 131.

The plurality of wire bonds 740 are coupled to the integrated device 104 and at least one metallization interconnect from the plurality of metallization interconnects 722 of the metallization portion 702. The plurality of wire bonds 740 may include a plurality of ball bonds. The plurality of wire bonds 740 may be coupled to and touching a front side of the integrated device 104. The plurality of wire bonds 740 may be coupled to and touching metallization interconnect(s) from the plurality of metallization interconnects 722. An electrical path between the integrated device 104 and the board 130 may include the plurality of wire bonds 740, at least one metallization interconnects from the plurality of metallization interconnects 722, at least one pillar interconnects from the plurality of pillar interconnects 725, a solder interconnect from the plurality of solder interconnects 790 and a board interconnect from the plurality of board interconnects 131.

The plurality of wire bonds 760 are coupled to the integrated device 106 and at least one metallization interconnect from the plurality of metallization interconnects 722 of the metallization portion 702. The plurality of wire bonds 760 may include a plurality of ball bonds. The plurality of wire bonds 760 may be coupled to and touching a front side of the integrated device 106. The plurality of wire bonds 760 may be coupled to and touching metallization interconnect(s) from the plurality of metallization interconnects 722. An electrical path between the integrated device 106 and the board 130 may include the plurality of wire bonds 760, at least one metallization interconnects from the plurality of metallization interconnects 722, at least one pillar interconnects from the plurality of pillar interconnects 725, a solder interconnect from the plurality of solder interconnects 790 and a board interconnect from the plurality of board interconnects 131.

The plurality of wire bonds 760 are coupled to the integrated device 108 and at least one metallization interconnect from the plurality of metallization interconnects 722 of the metallization portion 702. The plurality of wire bonds 780 may include a plurality of ball bonds. The plurality of wire bonds 780 may be coupled to and touching a front side of the integrated device 108. The plurality of wire bonds 780 may be coupled to and touching metallization interconnect(s) from the plurality of metallization interconnects 722. An electrical path between the integrated device 108 and the board 130 may include the plurality of wire bonds 780, at least one metallization interconnects from the plurality of metallization interconnects 722, at least one pillar interconnects from the plurality of pillar interconnects 725, a solder interconnect from the plurality of solder interconnects 790 and a board interconnect from the plurality of board interconnects 131.

The use of the plurality of wire bonds 720, the plurality of wire bonds 740, the plurality of wire bonds 760 and the plurality of wire bonds 780 may help reduce the pitch of interconnects of the package 700, since wire bonds have relatively thin diameters and high aspect ratios. This can help reduce the overall size and/or footprint of the package 700, while also providing high capacity bandwidth for the package.

### Exemplary Sequence for Fabricating a Package Comprising a Stack of Integrated Devices and Wire Bonds

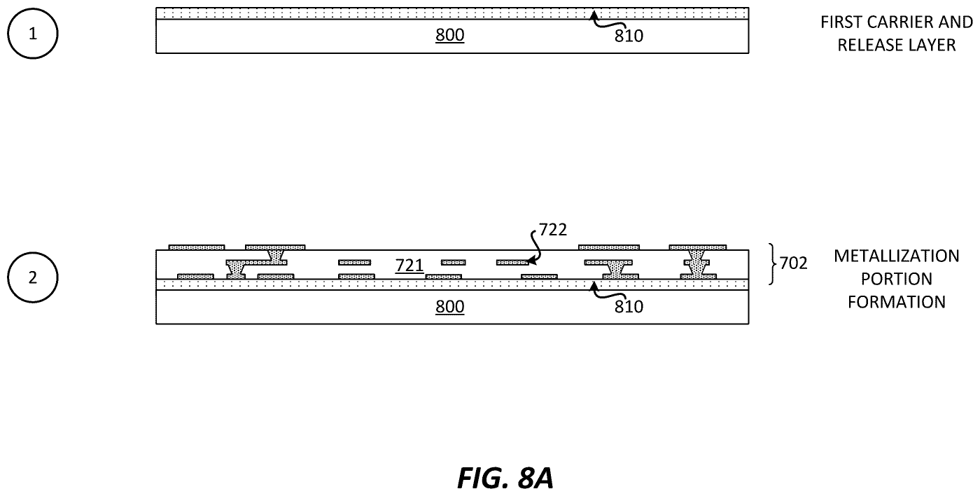

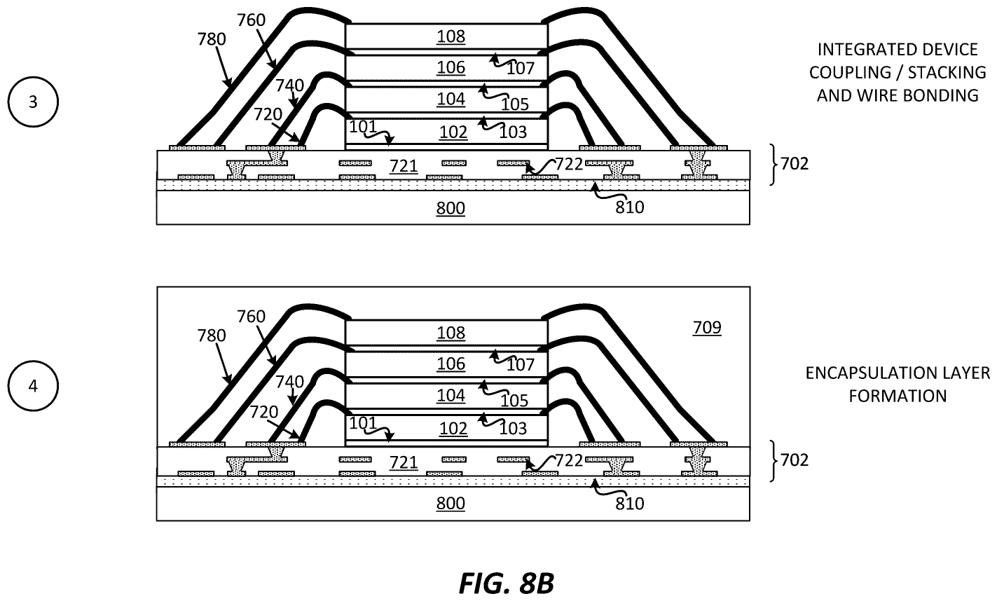

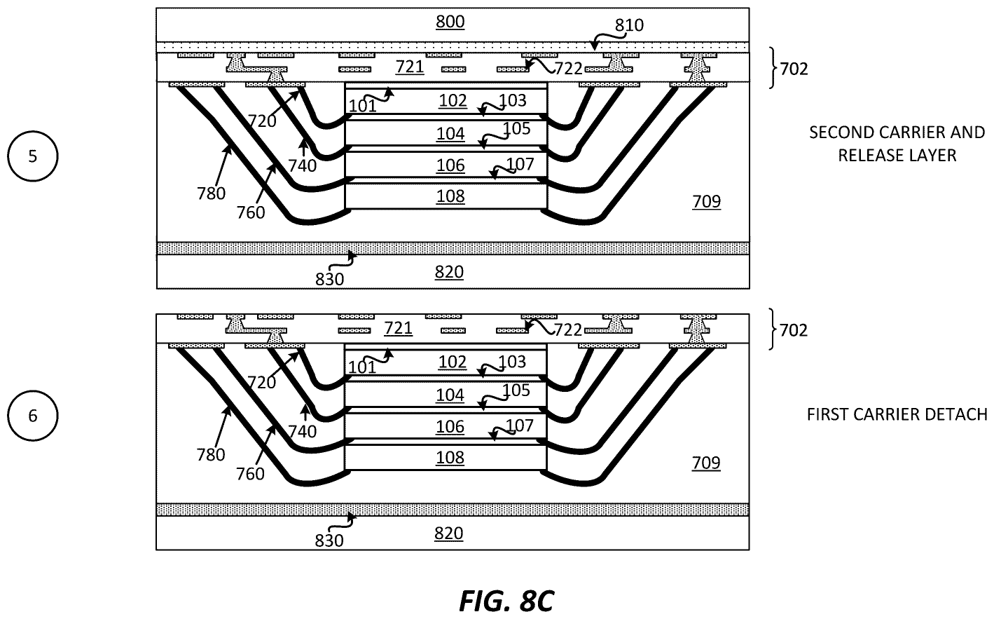

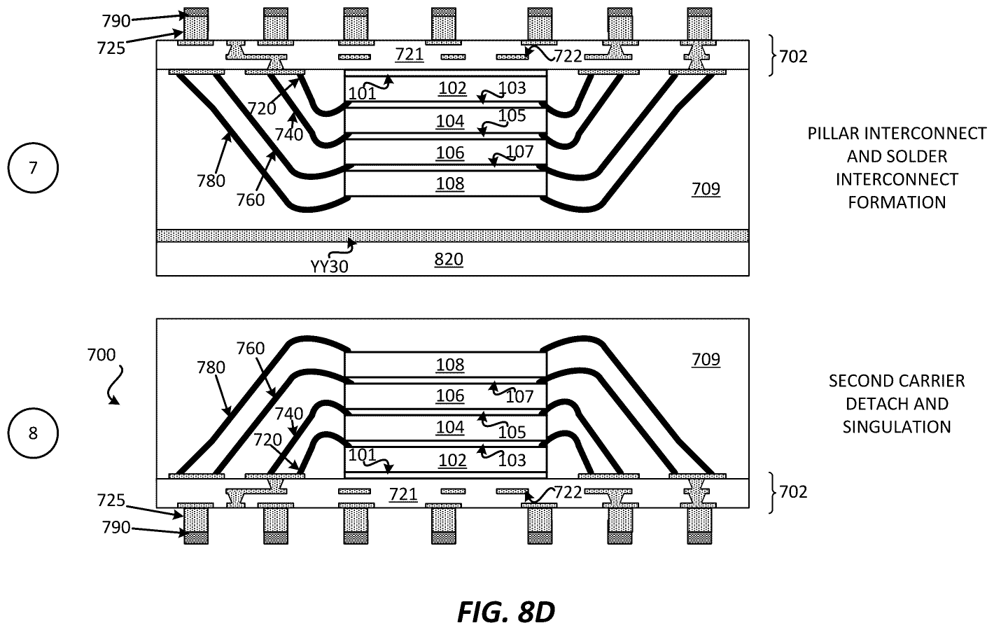

In some implementations, fabricating a package includes several processes. FIGS. 8A-8D illustrate an exemplary sequence for providing or fabricating a package. In some implementations, the sequence of FIGS. 8A-8D may be used to provide or fabricate the package 700. However, the process of FIGS. 8A-8D may be used to fabricate any of the packages described in the disclosure.

It should be noted that the sequence of FIGS. 8A-8D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 8A, illustrates a state after a carrier 800 and a release layer 810 are provided. The carrier 800 may include glass or silicon. Different implementations may use different materials for the carrier 800. The release layer 810 may include an adhesive.

Stage 2 illustrates a state after a metallization portion 702 is formed over the carrier 800 and the release layer 810. The metallization portion 702 may include at least one dielectric layer 721 and a plurality of metallization interconnects 722. In some implementations, a deposition process, a lamination process, an etching process (e.g., photo etching process), a laser process, an exposure process, a development process, a lithography process, a plating process, and/or a strip process may be used to form the metallization portion 702. An example of forming a metallization portion is illustrated and described below in at least FIGS. 14A-14B.

Stage 3, as shown in FIG. 8B, illustrates a state after (i) a plurality of integrated devices are coupled to the metallization portion 702 and (ii) a plurality of wire bonds are coupled to the integrated devices and the metallization portion 702. The plurality of wire bonds may include a plurality of ball bonds. Below is an example of a sequence for coupling integrated devices and forming a plurality of wire bonds.

In one example, the integrated device 102 may be coupled to the metallization portion 702 through the adhesive 101. A back side of the integrated device 102 may be coupled to the metallization portion 702 through the adhesive 101. A plurality of wire bonds 720 may be formed and coupled to the integrated device 102 and the metallization portion 702 through a wire bonding process. The plurality of wire bonds 720 may be coupled to pads of the front side of the integrated device 102. The plurality of wire bonds 720 may be formed from the integrated device 102 to a metallization interconnect from the plurality of metallization interconnects 722 of the metallization portion 702. In some implementations, the plurality of wire bonds 720 may be formed a metallization interconnect from the plurality of metallization interconnects 722 of the metallization portion 702.

Next, the integrated device 104 may be coupled to the integrated device 102 through the adhesive 103. For example, the backside of the integrated device 104 may be coupled to the front side of the integrated device 102 through the adhesive 103. The adhesive 103 may encapsulate part of the plurality of wire bonds 720 located between the integrated device 102 and the integrated device 104. A plurality of wire bonds 740 may be formed and coupled to the integrated device 104 and to the plurality of metallization interconnects 722 of the metallization portion 702 through a wire bonding process. The plurality of wire bonds 740 may be coupled to pads of the front side of the integrated device 104. The plurality of wire bonds 740 may be formed from the integrated device 104 to a metallization interconnect from the plurality of metallization interconnects 722 of the metallization portion 702. In some implementations, the plurality of wire bonds 740 may be formed from a metallization interconnect from the plurality of metallization interconnects 722 to the integrated device 104.

Next, the integrated device 106 may be coupled to the integrated device 104 through the adhesive 105. For example, the backside of the integrated device 106 may be coupled to the front side of the integrated device 104 through the adhesive 105. The adhesive 105 may encapsulate part of the plurality of wire bonds 740 located between the integrated device 104 and the integrated device 106. A plurality of wire bonds 760 may be formed and coupled to the integrated device 106 and to the plurality of metallization interconnects 722 of the metallization portion 702 through a wire bonding process. The plurality of wire bonds 760 may be coupled to pads of the front side of the integrated device 106. The plurality of wire bonds 760 may be formed from the integrated device 106 to a metallization interconnect from the plurality of metallization interconnects 722 of the metallization portion 702. In some implementations, the plurality of wire bonds 760 may be formed from a metallization interconnect from the plurality of metallization interconnects 722 to the integrated device 106.

Next, the integrated device 108 may be coupled to the integrated device 106 through the adhesive 107. For example, the backside of the integrated device 108 may be coupled to the front side of the integrated device 106 through the adhesive 107. The adhesive 107 may encapsulate part of the plurality of wire bonds 760 located between the integrated device 106 and the integrated device 108. A plurality of wire bonds 780 may be formed and coupled to the integrated device 108 and to the plurality of metallization interconnects 722 of the metallization portion 702 through a wire bonding process. The plurality of wire bonds 780 may be coupled to pads of the front side of the integrated device 108. The plurality of wire bonds 780 may be formed from the integrated device 108 to a metallization interconnect from the plurality of metallization interconnects 722 of the metallization portion 702. In some implementations, the plurality of wire bonds 780 may be formed from a metallization interconnect from the plurality of metallization interconnects 722 to the integrated device 108.

The above is merely an example of a sequence of coupling integrated devices and forming a plurality of wire bonds. Different implementations may have different sequences for coupling integrated devices and forming the plurality of wire bonds.

Stage 4 illustrates a state after an encapsulation layer 709 is provided and coupled to the metallization portion 702. The encapsulation layer 709 may at least partially encapsulate the integrated device 102, the integrated device 104, the integrated device 106, the integrated device 108, the adhesive 101, the adhesive 103, the adhesive 105, the adhesive 107, the plurality of wire bonds 720, the plurality of wire bonds 740, the plurality of wire bonds 760 and/or the plurality of wire bonds 780. The encapsulation layer 709 may include a mold, a resin, an epoxy and/or a filler. The encapsulation layer 709 may be provided by using a compression and transfer molding process, a sheet molding process, or a liquid molding process. The encapsulation layer 709 may be over molded. In some implementations, a planarization process of the encapsulation layer 709 may be performed. A portion of the encapsulation layer 709 may be removed and/or grinded off.

Stage 5, as shown in FIG. 8C, illustrates a state after a second carrier 820 is coupled to the encapsulation layer 709 through a release layer 830. The release layer 830 may include an adhesive. The second carrier 820 may be similar to the carrier 800. The second carrier 820 may include a similar material and/or a different material from the carrier 800.

Stage 6 illustrates a state after the carrier 800 and the release layer 810 are detached from the metallization portion 702.

Stage 7, as shown in FIG. 8D, illustrates a state after a plurality of pillar interconnects 725 are formed. The plurality of pillar interconnects 725 may be formed and coupled to the plurality of metallization interconnects 722 of the metallization portion 702. A plating process may be used to form the plurality of pillar interconnects 725. Stage 7 also illustrates a state after a plurality of solder interconnects 790 are coupled to the plurality of pillar interconnects 725. A pasting process may be used to couple the plurality of solder interconnects 790 to the plurality of pillar interconnects 725.

Stage 8 illustrates a state after the carrier 820 and the release layer 830 are detached from the encapsulation layer 709. Stage 8 may illustrate an example of the package 700.

### Exemplary Flow Diagram of a Method for Fabricating a Package Comprising a Stack of Integrated Devices and Wire Bonds

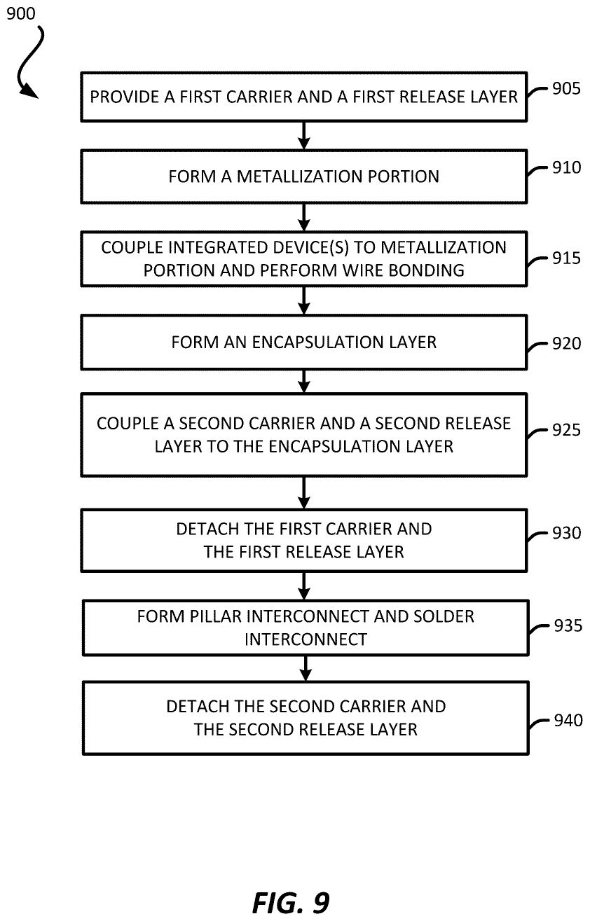

In some implementations, fabricating a package includes several processes. FIG. 9 illustrates an exemplary flow diagram of a method 900 for providing or fabricating a package. In some implementations, the method 900 of FIG. 9 may be used to provide or fabricate the package 700 described in the disclosure. However, the method 900 may be used to provide or fabricate any of the packages described in the disclosure.

It should be noted that the method 900 of FIG. 9 may combine one or more processes in order to simplify and/or clarify the method for providing or fabricating a package. In some implementations, the order of the processes may be changed or modified.

The method provides (at 905) a first carrier and a first release layer. Stage 1 of FIG. 8A, illustrates and describes an example of a state after a carrier 800 and a release layer 810 are provided. The carrier 800 may include glass or silicon. Different implementations may use different materials for the carrier 800. The release layer 810 may be an adhesive.

The method forms (at 910) a metallization portion. Stage 2 of FIG. 8A, illustrates and describes an example of a state after a metallization portion 702 is formed over the carrier 800 and the release layer 810. The metallization portion 702 may include at least one dielectric layer 721 and a plurality of metallization interconnects 722. In some implementations, a deposition process, a lamination process, an etching process (e.g., photo etching process), a laser process, an exposure process, a development process, a lithography process, a plating process, and/or a strip process may be used to form the metallization portion 702. An example of forming a metallization portion is illustrated and described below in at least FIGS. 14A-14B.

The method couples (at 915) a plurality of integrated devices to the metallization portion and forms a plurality of wire bonds. Stage 3 of FIG. 8B, illustrates and describes an example of a state after (i) a plurality of integrated devices are coupled to the metallization portion 702 and (ii) a plurality of wire bonds are coupled to the integrated devices and the metallization portion 702. The plurality of wire bonds may include a plurality of ball bonds. Below is an example of a sequence for coupling integrated devices and forming a plurality of wire bonds.

In one example, the integrated device 102 may be coupled to the metallization portion 702 through the adhesive 101. A back side of the integrated device 102 may be coupled to the metallization portion 702 through the adhesive 101. A plurality of wire bonds 720 may be formed and coupled to the integrated device 102 and the metallization portion 702 through a wire bonding process. The plurality of wire bonds 720 may be coupled to pads of the front side of the integrated device 102. The plurality of wire bonds 720 may be formed from the integrated device 102 to a metallization interconnect from the plurality of metallization interconnects 722 of the metallization portion 702. In some implementations, the plurality of wire bonds 720 may be formed a metallization interconnect from the plurality of metallization interconnects 722 of the metallization portion 702.

Next, the integrated device 104 may be coupled to the integrated device 102 through the adhesive 103. For example, the backside of the integrated device 104 may be coupled to the front side of the integrated device 102 through the adhesive 103. The adhesive 103 may encapsulate part of the plurality of wire bonds 720 located between the integrated device 102 and the integrated device 104. A plurality of wire bonds 740 may be formed and coupled to the integrated device 104 and to the plurality of metallization interconnects 722 of the metallization portion 702 through a wire bonding process. The plurality of wire bonds 740 may be coupled to pads of the front side of the integrated device 104. The plurality of wire bonds 740 may be formed from the integrated device 104 to a metallization interconnect from the plurality of metallization interconnects 722 of the metallization portion 702. In some implementations, the plurality of wire bonds 740 may be formed from a metallization interconnect from the plurality of metallization interconnects 722 to the integrated device 104.

Next, the integrated device 106 may be coupled to the integrated device 104 through the adhesive 105. For example, the backside of the integrated device 106 may be coupled to the front side of the integrated device 104 through the adhesive 105. The adhesive 105 may encapsulate part of the plurality of wire bonds 740 located between the integrated device 104 and the integrated device 106. A plurality of wire bonds 760 may be formed and coupled to the integrated device 106 and to the plurality of metallization interconnects 722 of the metallization portion 702 through a wire bonding process. The plurality of wire bonds 760 may be coupled to pads of the front side of the integrated device 106. The plurality of wire bonds 760 may be formed from the integrated device 106 to a metallization interconnect from the plurality of metallization interconnects 722 of the metallization portion 702. In some implementations, the plurality of wire bonds 760 may be formed from a metallization interconnect from the plurality of metallization interconnects 722 to the integrated device 106.

Next, the integrated device 108 may be coupled to the integrated device 106 through the adhesive 107. For example, the backside of the integrated device 108 may be coupled to the front side of the integrated device 106 through the adhesive 107. The adhesive 107 may encapsulate part of the plurality of wire bonds 760 located between the integrated device 106 and the integrated device 108. A plurality of wire bonds 780 may be formed and coupled to the integrated device 108 and to the plurality of metallization interconnects 722 of the metallization portion 702 through a wire bonding process. The plurality of wire bonds 780 may be coupled to pads of the front side of the integrated device 108. The plurality of wire bonds 780 may be formed from the integrated device 108 to a metallization interconnect from the plurality of metallization interconnects 722 of the metallization portion 702. In some implementations, the plurality of wire bonds 780 may be formed from a metallization interconnect from the plurality of metallization interconnects 722 to the integrated device 108.

The above is merely an example of a sequence of coupling integrated devices and forming a plurality of wire bonds. Different implementations may have different sequences for coupling integrated devices and forming the plurality of wire bonds.

The method forms (at 920) an encapsulation layer. Stage 4 of FIG. 8B, illustrates and describes an example of a state after an encapsulation layer 709 is provided and coupled to the metallization portion 702. The encapsulation layer 709 may at least partially encapsulate the integrated device 102, the integrated device 104, the integrated device 106, the integrated device 108, the adhesive 101, the adhesive 103, the adhesive 105, the adhesive 107, the plurality of wire bonds 720, the plurality of wire bonds 740, the plurality of wire bonds 760 and/or the plurality of wire bonds 780. The encapsulation layer 709 may include a mold, a resin, an epoxy and/or a filler. The encapsulation layer 709 may be provided by using a compression and transfer molding process, a sheet molding process, or a liquid molding process. The encapsulation layer 709 may be over molded. In some implementations, a planarization process of the encapsulation layer 709 may be performed. A portion of the encapsulation layer 709 may be removed and/or grinded off.

The method couples (at 925) a second carrier and a second release layer to the encapsulation layer. Stage 5 of FIG. 8C, illustrates and describes an example of a state after a second carrier 820 is coupled to the encapsulation layer 709 through a release layer 830. The release layer 830 may be an adhesive. The second carrier 820 may be similar to the carrier 800. The second carrier 820 may include a similar material and/or a different material from the carrier 800.

The method detaches (at 930) the first carrier and the first release layer. Stage 6 of FIG. 8C, illustrates and describes an example of a state after the carrier 800 and the release layer 810 are detached from the metallization portion 702.

The method forms (at 935) a plurality of pillar interconnects and a plurality of solder interconnects. Stage 7 of FIG. 8D, illustrates and describes an example of a state after a plurality of pillar interconnects 725 are formed. The plurality of pillar interconnects 725 may be formed and coupled to the plurality of metallization interconnects 722 of the metallization portion 702. A plating process may be used to form the plurality of pillar interconnects 725. Stage 7 also illustrates a state after a plurality of solder interconnects 790 are coupled to the plurality of pillar interconnects 725. A pasting process may be used to couple the plurality of solder interconnects 790 to the plurality of pillar interconnects 725.

The method detaches (at 940) the second carrier and the second release layer. Stage 8 of FIG. 8D, illustrates and describes an example of a state after the second carrier 820 and the release layer 830 are detached from the encapsulation layer 709. Stage 8 may illustrate an example of the package 700.

### Exemplary Package Comprising a Stack of Integrated Devices and Wire Bonds

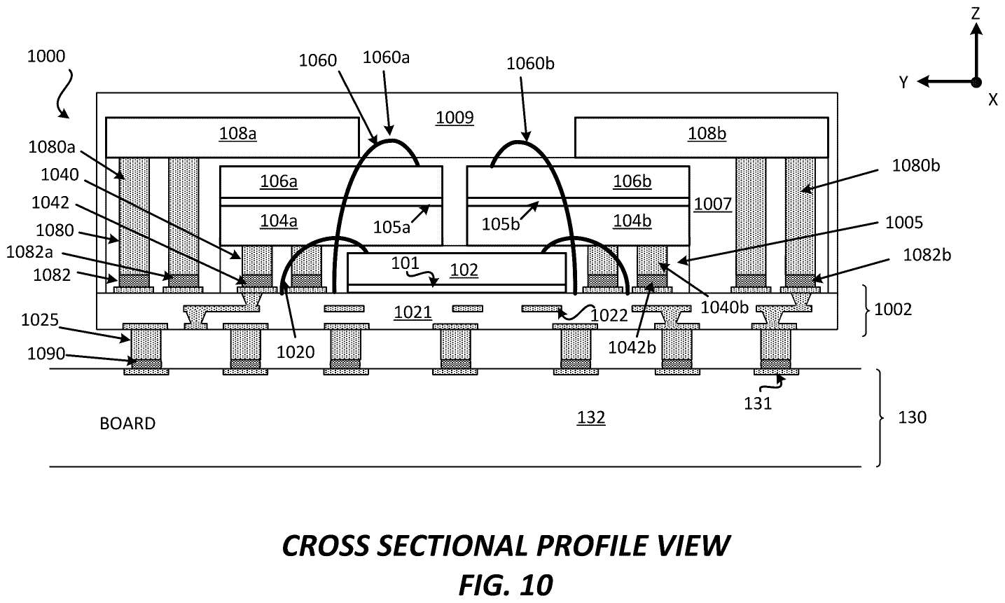

FIG. 10 illustrates a cross sectional profile view of a package 1000 that includes a plurality of integrated devices, a plurality of wire bonds and a metallization portion. The package 1000 is coupled to a board 130 through a plurality of solder interconnects 1090. The board 130 includes at least one board dielectric layer 132 and a plurality of board interconnects 131. The board 130 may include a printed circuit board (PCB). In some implementations, the package 1000 may be coupled to a substrate (e.g., laminated substrate, coreless substrate, cored substrate) instead of the board 130.

The package 1000 includes an integrated device 102, an integrated device 104a, an integrated device 106a, an integrated device 108a, an integrated device 104b, an integrated device 106b, an integrated device 108b, an adhesive 101, an adhesive 105a, an adhesive 105b, a non-conducting material layer 1005, a non-conducting material layer 1007, a plurality of wire bonds 1020, a plurality of wire bonds 1060, a plurality of post interconnects 1040, a plurality of post interconnects 1080, an encapsulation layer 1009, a metallization portion 1002 and a plurality of pillar interconnects 1025. The metallization portion 1002 may include at least one dielectric layer 1021 and a plurality of metallization interconnects 1022. The encapsulation layer 1009 may be coupled to the metallization portion 1002. The plurality of wire bonds 1060 may include a plurality of wire bonds 1060a and a plurality of wire bonds 1060b. The plurality of post interconnects 1040 may include a plurality of post interconnects 1040a and a plurality of post interconnects 1040b.

The integrated device 102, the integrated device 104a, the integrated device 104b, the integrated device 106a, the integrated device 106b, the integrated device 108a and/or the integrated device 108b may include a memory (e.g., memory chip, memory die). For example, one or more of the integrated device 102, the integrated device 104a, the integrated device 104b, the integrated device 106a, the integrated device 106b, the integrated device 108a and/or the integrated device 108b may be a memory device (e.g., memory chip, memory die).

A back side of the integrated device 102 may be coupled to the metallization portion 1002 through an adhesive 101 (e.g., die attach film (DAF)). The plurality of wire bonds 1020 are coupled to a front side of the integrated device 102 and a plurality of metallization interconnects 1022 of the metallization portion 1002. The plurality of wire bonds 1020 may be coupled to pads of the integrated device 102.

The integrated device 104a is coupled to the plurality of metallization interconnects 1022 of the metallization portion 1002 through a plurality of post interconnects 1040a and a plurality of solder interconnects 1042a. A front side of the integrated device 104a may face in the direction of the metallization portion 1002. The integrated device 104a may at least partially vertically overlap with the integrated device 102. The integrated device 104b is coupled to the plurality of metallization interconnects 1022 of the metallization portion 1002 through a plurality of post interconnects 1040b and a plurality of solder interconnects 1042b. A front side of the integrated device 104b may face in the direction of the metallization portion 1002. The integrated device 104b may at least partially vertically overlap with the integrated device 102. The integrated device 104b be located laterally to the integrated device 104a, and vice versa. A non-conducting material layer 1005 (e.g., non-conducting paste) may be located between the integrated device 104a and the metallization portion 1002. The non-conducting material layer 1005 may also be located between the integrated device 104b and the metallization portion 1002. The non-conducting material layer 1005 may also be located over the front side of the integrated device 102. The non-conducting material layer 1005 may be include a non-conducting paste.

A back side of the integrated device 106a may be coupled to a back side of the integrated device 104a through an adhesive 105a (e.g., die attach film (DAF)). The integrated device 106a may vertically overlap with the integrated device 104a. A back side of the integrated device 106b may be coupled to a back side of the integrated device 104b through an adhesive 105b (e.g., die attach film (DAF)). The integrated device 106b may vertically overlap with the integrated device 104b. The integrated device 106b be located laterally to the integrated device 106a, and vice versa. The plurality of wire bonds 1060a are coupled to a front side of the integrated device 106a and a plurality of metallization interconnects 1022 of the metallization portion 1002. The plurality of wire bonds 1060a may be coupled to pads of the integrated device 106a. The plurality of wire bonds 1060b are coupled to a front side of the integrated device 106b and a plurality of metallization interconnects 1022 of the metallization portion 1002. The plurality of wire bonds 1060b may be coupled to pads of the integrated device 106b.

The integrated device 108a is coupled to the plurality of metallization interconnects 1022 of the metallization portion 1002 through a plurality of post interconnects 1080a and a plurality of solder interconnects 1082a. A front side of the integrated device 108a may face in the direction of the metallization portion 1002. The integrated device 108a may at least partially vertically overlap with the integrated device 106a. The integrated device 108b is coupled to the plurality of metallization interconnects 1022 of the metallization portion 1002 through a plurality of post interconnects 1080b and a plurality of solder interconnects 1082b. A front side of the integrated device 108b may face in the direction of the metallization portion 1002. The integrated device 108b may at least partially vertically overlap with the integrated device 106b. The integrated device 108b be located laterally to the integrated device 108a, and vice versa. A non-conducting material layer 1007 (e.g., non-conducting paste) may be located between the integrated device 108a and the metallization portion 1002. The non-conducting material layer 1007 may also be located between the integrated device 108b and the metallization portion 1002. The non-conducting material layer 1007 may also be at least partially encapsulate the integrated device 104a, the integrated device 104b, the integrated device 106a and/or the integrated device 106b. The non-conducting material layer 1007 may include a non-conducting paste.

The encapsulation layer 109 may at least partially encapsulate the integrated device 102, the integrated device 104a, the integrated device 106a, the integrated device 108a, the integrated device 104b, the integrated device 106b, the integrated device 108b, the plurality of wire bonds 1020, the plurality of wire bonds 1060, the plurality of post interconnects 1080. The encapsulation layer 1009 may include a mold, a resin, an epoxy and/or a filler. The encapsulation layer 1009 may include a different material and/or a different composition from the non-conducting material layer 1005 and/or the non-conducting material layer 1007.

The package 1000 provides a compact package that uses wire bonds and post interconnects, with a minimized footprint, while having high density interconnects for high bandwidth capacity (e.g., high bandwidth memory capacity) of the package.

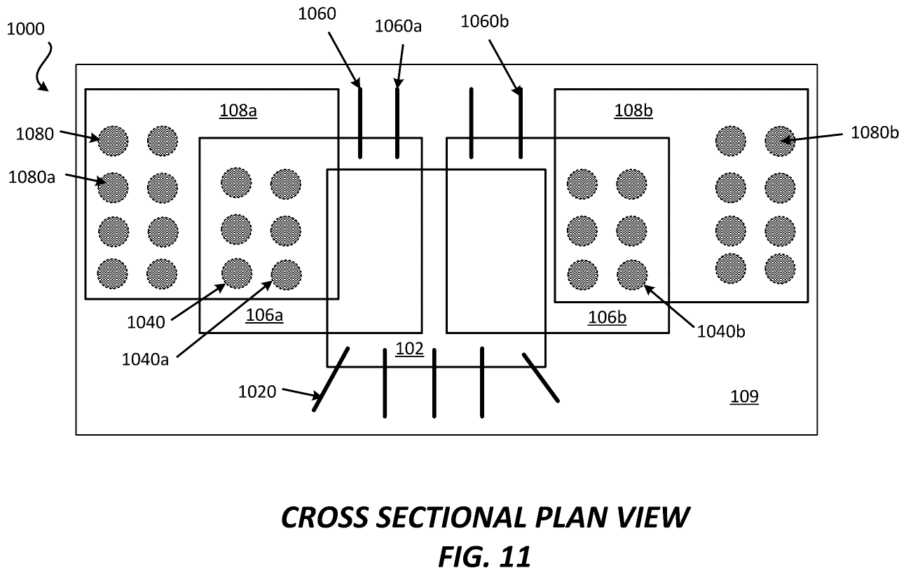

FIG. 11 illustrates an exemplary plan view of the package 1000. As shown in FIG. 11, the plurality of wire bonds 120 are coupled to the integrated device 102 and the metallization portion 1002. The integrated device 106a vertically overlaps with at least a portion of the integrated device 102. The integrated device 106b vertically overlaps with at least a portion of the integrated device 102. The plurality of wire bonds 1060a are coupled to the integrated device 106a and the metallization portion 1002. The plurality of wire bonds 1060b are coupled to the integrated device 106b and the metallization portion 1002. Although not show in FIG. 11, the integrated device 104a vertically overlaps with at least a portion of the integrated device 106a. Similarly, the integrated device 104b (not shown) vertically overlaps with at least a portion of the integrated device 106b. The plurality of post interconnects 1040a may be coupled to the integrated device 104a. The plurality of post interconnects 1040b may be coupled to the integrated device 104b. The integrated device 108a may vertically overlaps with at least a portion of the integrated device 106a. The plurality of post interconnects 1080a may be coupled to the integrated device 108a. The integrated device 108b may vertically overlaps with at least a portion of the integrated device 106b. The plurality of post interconnects 1080b may be coupled to the integrated device 108b.

### Exemplary Sequence for Fabricating a Package Comprising a Stack of Integrated Devices and Wire Bonds

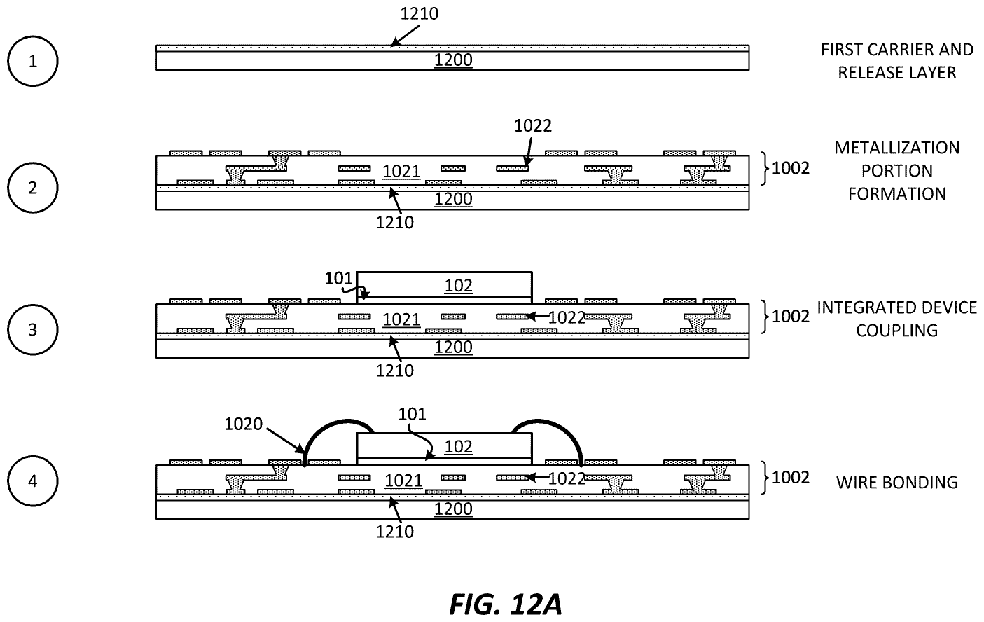

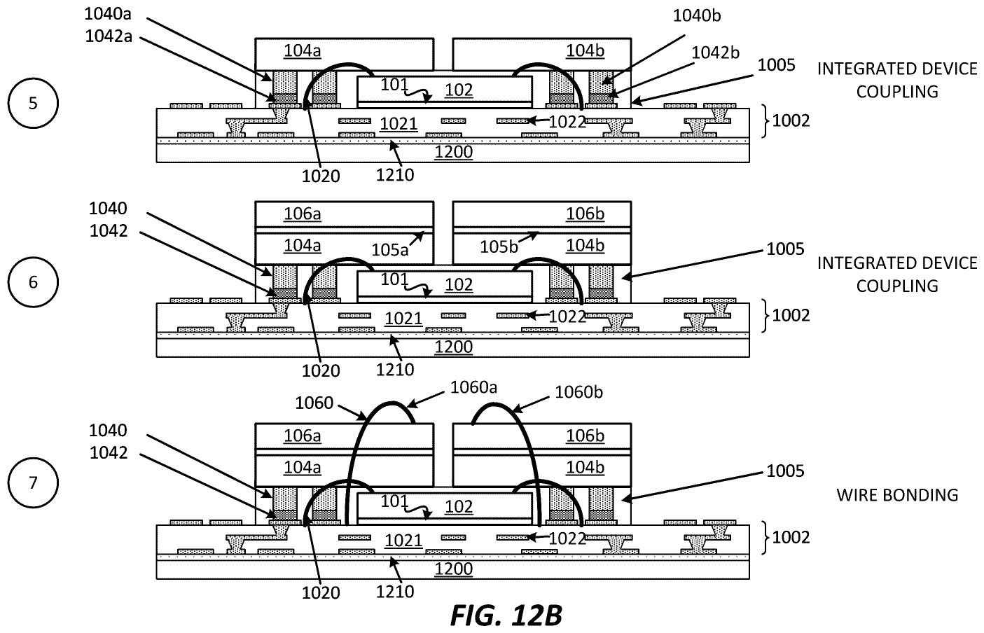

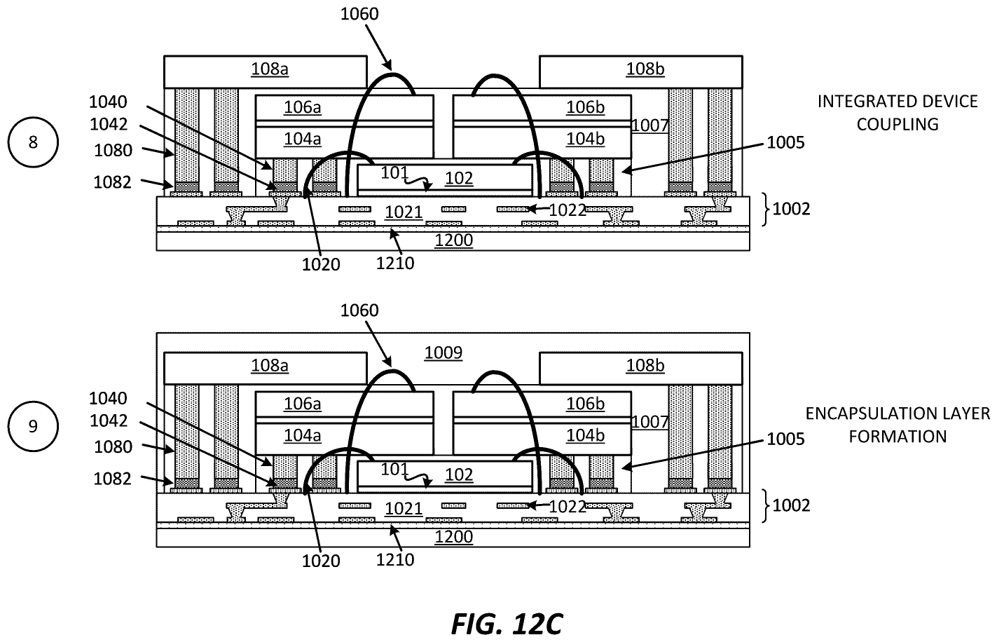

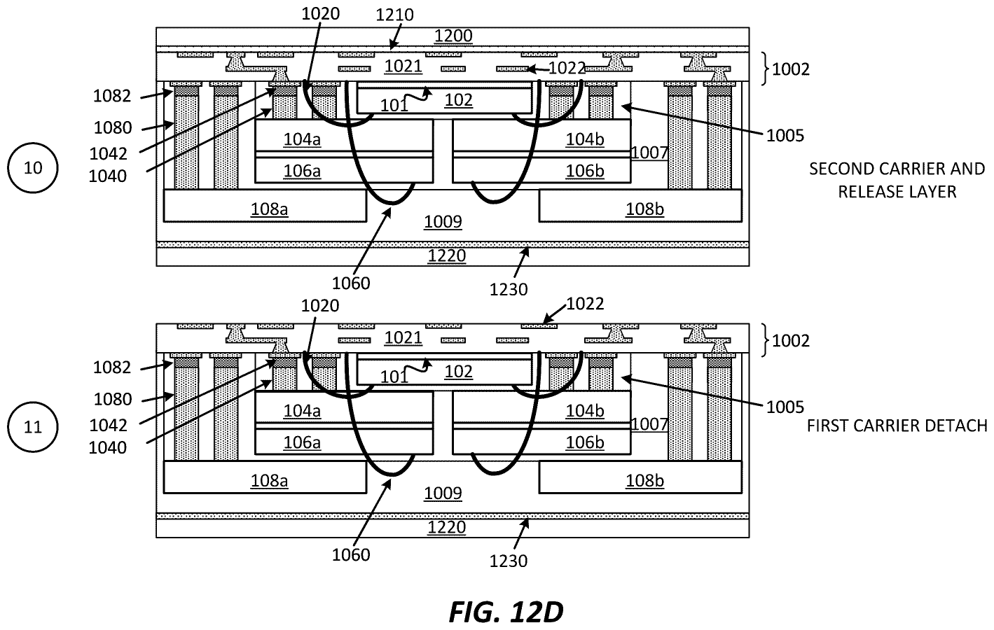

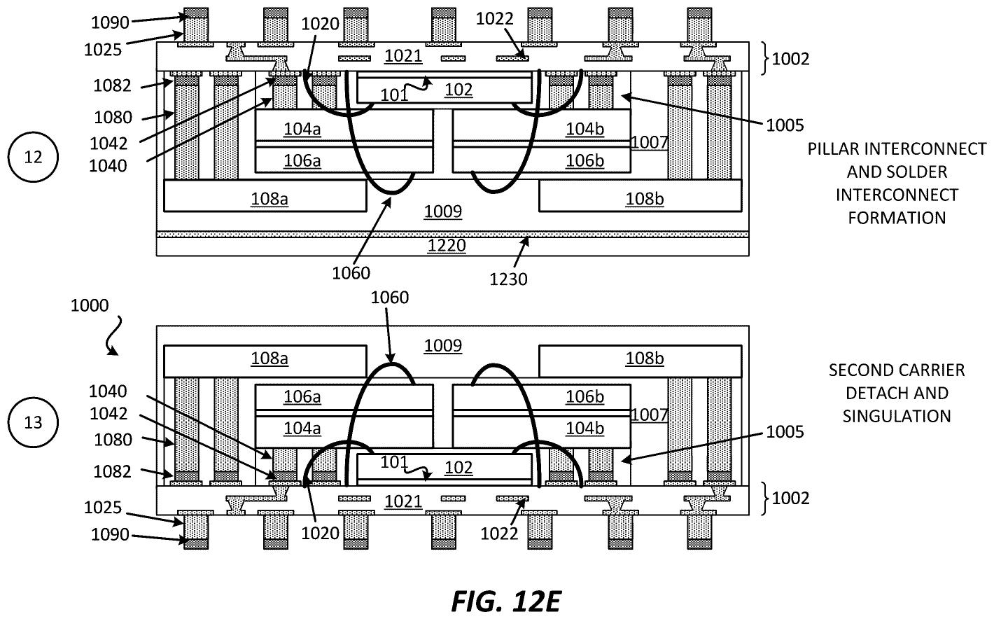

In some implementations, fabricating a package includes several processes. FIGS. 12A-12E illustrate an exemplary sequence for providing or fabricating a package. In some implementations, the sequence of FIGS. 12A-12E may be used to provide or fabricate the package 1000. However, the process of FIGS. 12A-12E may be used to fabricate any of the packages described in the disclosure.

It should be noted that the sequence of FIGS. 12A-12E may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 12A, illustrates a state after a carrier 1200 and a release layer 1210 are provided. The carrier 1200 may include glass or silicon. Different implementations may use different materials for the carrier 1200. The release layer 1210 may be an adhesive.

Stage 2 illustrates a state after a metallization portion 1002 is formed over the carrier 1200 and the release layer 1210. The metallization portion 1002 may include at least one dielectric layer 1021 and a plurality of metallization interconnects 1022. In some implementations, a deposition process, a lamination process, an etching process (e.g., photo etching process), a laser process, an exposure process, a development process, a lithography process, a plating process, and/or a strip process may be used to form the metallization portion 1002. An example of forming a metallization portion is illustrated and described below in at least FIGS. 14A-14B.

Stage 3 illustrates a state after the integrated device 102 may be coupled to the metallization portion 1002 through the adhesive 101. A back side of the integrated device 102 may be coupled to the metallization portion 1002 through the adhesive 101.

Stage 4 illustrates a state after a plurality of wire bonds 1020 are formed and coupled to the integrated device 102 and the metallization portion 1002, through a wire bonding process. The plurality of wire bonds 1020 may be coupled to a front side of the integrated device 102 and a plurality of metallization interconnects 1022 of the metallization portion 1002.

Stage 5, as shown in FIG. 12B, illustrates a state after the integrated device 104a is coupled to plurality of metallization interconnects 1022 of the metallization portion 1002, through a plurality of post interconnects 1040a and a plurality of solder interconnects 1042a. The plurality of solder interconnects 1042a may touch the plurality of post interconnects 1040a and the plurality of metallization interconnects 1022.

Stage 5 also illustrates a state after the integrated device 104b is coupled to plurality of metallization interconnects 1022 of the metallization portion 1002, through a plurality of post interconnects 1040b and a plurality of solder interconnects 1042b. The plurality of solder interconnects 1042b may touch the plurality of post interconnects 1040b and the plurality of metallization interconnects 1022.

A non-conducting material layer 1005 (e.g., NCP) may be provided between the integrated device 104a and the metallization portion 1002. The non-conducting material layer 1005 may also be provided between the integrated device 104b and the metallization portion 1002. The non-conducting material layer 1005 may be dispensed on the surface of the metallization portion 1002 and on a front surface of the integrated device 102. The non-conducting material layer 1005 may be provided before the integrated device 104a and/or the integrated device 104b may be coupled to the metallization portion 1002. The integrated device 104a and/or the integrated device 104b may be coupled to the metallization portion 1002 through thermal compression and non-conducting paste bonding (e.g., TC-NCP bonding). The non-conducting material layer 1005 may include a non-conducting paste.

Stage 6 illustrates a state after a back side of the integrated device 106a is coupled to a back side of the integrated device 104a through an adhesive 105a. Stage 6 also illustrates a state after a back side of the integrated device 106b is coupled to a back side of the integrated device 104b through an adhesive 105b.

Stage 7 illustrates a state after a plurality of wire bonds 1060a are formed and coupled to the integrated device 106a and the metallization portion 1002, through a wire bonding process. The plurality of wire bonds 1060a may be coupled to a front side of the integrated device 106a and a plurality of metallization interconnects 1022 of the metallization portion 1002.

Stage 7 also illustrates a state after a plurality of wire bonds 1060b are formed and coupled to the integrated device 106b and the metallization portion 1002, through a wire bonding process. The plurality of wire bonds 1060b may be coupled to a front side of the integrated device 106b and a plurality of metallization interconnects 1022 of the metallization portion 1002.

Stage 8, as shown in FIG. 12C, illustrates a state after the integrated device 108a is coupled to plurality of metallization interconnects 1022 of the metallization portion 1002, through a plurality of post interconnects 1080a and a plurality of solder interconnects 1082a. The plurality of solder interconnects 1082a may touch the plurality of post interconnects 1080a and the plurality of metallization interconnects 1022.

Stage 8 also illustrates a state after the integrated device 108b is coupled to plurality of metallization interconnects 1022 of the metallization portion 1002, through a plurality of post interconnects 1080b and a plurality of solder interconnects 1082b. The plurality of solder interconnects 1080b may touch the plurality of post interconnects 1080b and the plurality of metallization interconnects 1022.

A non-conducting material layer 1007 may be provided between the integrated device 108a and the metallization portion 1002. The non-conducting material layer 1007 may also be provided between the integrated device 108b and the metallization portion 1002. The non-conducting material layer 1007 may be dispensed on the surface of the metallization portion 1002 and on a front surface of the integrated device 106a and a front surface of the integrated device 106b. The non-conducting material layer 1007 may be provided before the integrated device 108a and/or the integrated device 108b may be coupled to the metallization portion 1002. The integrated device 108a and/or the integrated device 108b may be coupled to the metallization portion 1002 through thermal compression and non-conducting paste bonding (e.g., TC-NCP bonding). The non-conducting material layer 1007 may include a non-conducting paste.

Stage 9 illustrates a state after an encapsulation layer 1009 is provided and coupled to the metallization portion 1002. The encapsulation layer 1009 may at least partially encapsulate the integrated device 102, the integrated device 104a, the integrated device 104b, the integrated device 106a, the integrated device 106b, the integrated device 108a and the integrated device 108b, the plurality of wire bonds 1020, the plurality of wire bonds 1060, the plurality of post interconnects 1040 and/or the plurality of post interconnects 1080. The encapsulation layer 1009 may include a mold, a resin, an epoxy and/or a filler. The encapsulation layer 1009 may be provided by using a compression and transfer molding process, a sheet molding process, or a liquid molding process. The encapsulation layer 1009 may be over molded. In some implementations, a planarization process of the encapsulation layer 1009 may be performed. A portion of the encapsulation layer 1009 may be removed and/or grinded off.

Stage 10, as shown in FIG. 12D, illustrates a state after a second carrier 1220 is coupled to the encapsulation layer 1009 through a release layer 1230. The release layer 1230 may be an adhesive. The second carrier 1220 may be similar to the carrier 1200. The second carrier 1220 may include a similar material and/or a different material from the carrier 1200.

Stage 11 illustrates a state after the carrier 1200 and the release layer 1210 are detached from the metallization portion 1002.

Stage 12, as shown in FIG. 12E, illustrates a state after a plurality of pillar interconnects 1025 are formed. The plurality of pillar interconnects 1025 may be formed and coupled to the plurality of metallization interconnects 1022 of the metallization portion 1002. A plating process may be used to form the plurality of pillar interconnects 1025. Stage 12 also illustrates a state after a plurality of solder interconnects 1090 are coupled to the plurality of pillar interconnects 1025. A pasting process may be used to couple the plurality of solder interconnects 1090 to the plurality of pillar interconnects 1025.

Stage 13 illustrates a state after the second carrier 1220 and the release layer 1230 are detached from the encapsulation layer 1009. Stage 13 may illustrate an example of the package 1000.

### Exemplary Flow Diagram of a Method for Fabricating a Package Comprising a Stack of Integrated Devices and Wire Bonds

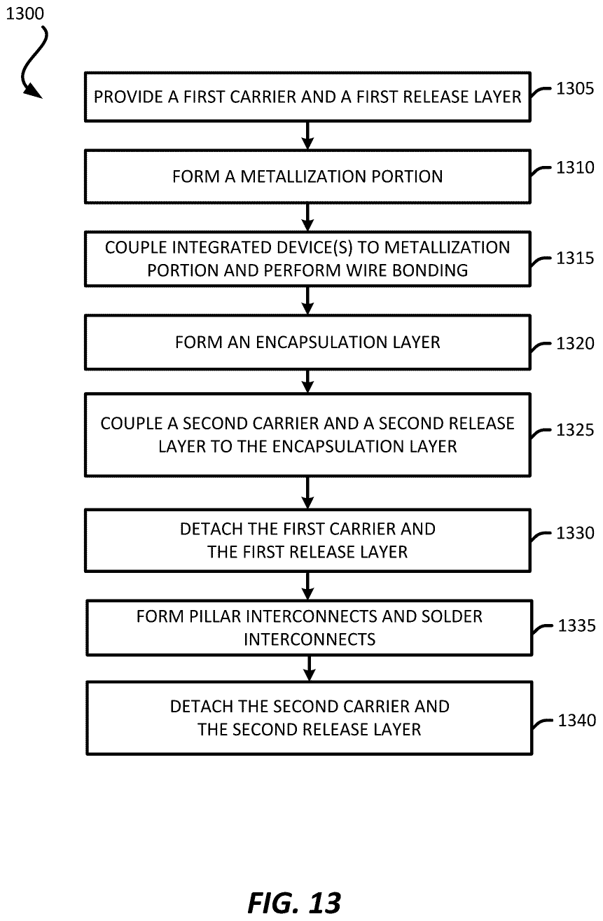

In some implementations, fabricating a package includes several processes. FIG. 13 illustrates an exemplary flow diagram of a method 1300 for providing or fabricating a package. In some implementations, the method 1300 of FIG. 13 may be used to provide or fabricate the package 1000 described in the disclosure. However, the method 1300 may be used to provide or fabricate any of the packages described in the disclosure.

It should be noted that the method 1300 of FIG. 13 may combine one or more processes in order to simplify and/or clarify the method for providing or fabricating a package. In some implementations, the order of the processes may be changed or modified.

The method provides (at 1305) a first carrier and a first release layer. Stage 1 of FIG. 12A, illustrates and describes an example of a state after a carrier 1200 and a release layer 1210 are provided. The carrier 1200 may include glass or silicon. Different implementations may use different materials for the carrier 1200. The release layer 1210 may be an adhesive.

The method forms (at 1310) a metallization portion. Stage 2 of FIG. 12A, illustrates and describes an example of a state after a metallization portion 1002 is formed over the carrier 1200 and the release layer 1210. The metallization portion 1002 may include at least one dielectric layer 1021 and a plurality of metallization interconnects 1022. In some implementations, a deposition process, a lamination process, an etching process (e.g., photo etching process), a laser process, an exposure process, a development process, a lithography process, a plating process, and/or a strip process may be used to form the metallization portion 1002. An example of forming a metallization portion is illustrated and described below in at least FIGS. 14A-14B.

The method couples (at 1315) integrated devices to the metallization portion and forms a plurality of wire bonds. Stage 3 of FIG. 12A through Stage 8 of FIG. 12C illustrates examples of coupling integrated devices to a metallization portion and forming a plurality of wire bonds.

Stage 3 of FIG. 12A, illustrates and describes an example of a state after the integrated device 102 may be coupled to the metallization portion 1002 through the adhesive 101. A back side of the integrated device 102 may be coupled to the metallization portion 1002 through the adhesive 101.

Stage 4 of FIG. 12A, illustrates and describes an example of a state after a plurality of wire bonds 1020 are formed and coupled to the integrated device 102 and the metallization portion 1002, through a wire bonding process. The plurality of wire bonds 1020 may be coupled to a front side of the integrated device 102 and a plurality of metallization interconnects 1022 of the metallization portion 1002.

Stage 5 of FIG. 12B, illustrates and describes an example of a state after the integrated device 104a is coupled to plurality of metallization interconnects 1022 of the metallization portion 1002, through a plurality of post interconnects 1040a and a plurality of solder interconnects 1042a. The plurality of solder interconnects 1042a may touch the plurality of post interconnects 1040a and the plurality of metallization interconnects 1022.

Stage 5 also illustrates a state after the integrated device 104b is coupled to plurality of metallization interconnects 1022 of the metallization portion 1002, through a plurality of post interconnects 1040b and a plurality of solder interconnects 1042b. The plurality of solder interconnects 1042b may touch the plurality of post interconnects 1040b and the plurality of metallization interconnects 1022.

A non-conducting material layer 1005 (e.g., NCP) may be provided between the integrated device 104a and the metallization portion 1002. The non-conducting material layer 1005 may also be provided between the integrated device 104b and the metallization portion 1002. The non-conducting material layer 1005 may be dispensed on the surface of the metallization portion 1002 and on a front surface of the integrated device 102. The non-conducting material layer 1005 may be provided before the integrated device 104a and/or the integrated device 104b may be coupled to the metallization portion 1002. The integrated device 104a and/or the integrated device 104b may be coupled to the metallization portion 1002 through thermal compression and non-conducting paste bonding (e.g., TC-NCP bonding). The non-conducting material layer 1005 may include a non-conducting paste.

Stage 6 of FIG. 12B, illustrates and describes an example of a state after a back side of the integrated device 106a is coupled to a back side of the integrated device 104a through an adhesive 105a. Stage 6 also illustrates a state after a back side of the integrated device 106b is coupled to a back side of the integrated device 104b through an adhesive 105b.

Stage 7 of FIG. 12B, illustrates and describes an example of a state after a plurality of wire bonds 1060a are formed and coupled to the integrated device 106a and the metallization portion 1002, through a wire bonding process. The plurality of wire bonds 1060a may be coupled to a front side of the integrated device 106a and a plurality of metallization interconnects 1022 of the metallization portion 1002.

Stage 7 also illustrates and describes an example of a state after a plurality of wire bonds 1060b are formed and coupled to the integrated device 106b and the metallization portion 1002, through a wire bonding process. The plurality of wire bonds 1060b may be coupled to a front side of the integrated device 106b and a plurality of metallization interconnects 1022 of the metallization portion 1002.

Stage 8 of FIG. 12C, illustrates and describes an example of a state after the integrated device 108a is coupled to plurality of metallization interconnects 1022 of the metallization portion 1002, through a plurality of post interconnects 1080a and a plurality of solder interconnects 1082a. The plurality of solder interconnects 1082a may touch the plurality of post interconnects 1080a and the plurality of metallization interconnects 1022.

Stage 8 also illustrates and describes an example of a state after the integrated device 108b is coupled to plurality of metallization interconnects 1022 of the metallization portion 1002, through a plurality of post interconnects 1080b and a plurality of solder interconnects 1082b. The plurality of solder interconnects 1080b may touch the plurality of post interconnects 1080b and the plurality of metallization interconnects 1022.

A non-conducting material layer 1007 may be provided between the integrated device 108a and the metallization portion 1002. The non-conducting material layer 1007 may also be provided between the integrated device 108b and the metallization portion 1002. The non-conducting material layer 1007 may be dispensed on the surface of the metallization portion 1002 and on a front surface of the integrated device 106a and a front surface of the integrated device 106b. The non-conducting material layer 1007 may be provided before the integrated device 108a and/or the integrated device 108b may be coupled to the metallization portion 1002. The integrated device 108a and/or the integrated device 108b may be coupled to the metallization portion 1002 through thermal compression and non-conducting paste bonding (e.g., TC-NCP bonding). The non-conducting material layer 1007 may include a non-conducting paste.

The method forms (at 1320) an encapsulation layer. Stage 9 of FIG. 12C, illustrates and describes an example of a state after an encapsulation layer 1009 is provided and coupled to the metallization portion 1002. The encapsulation layer 1009 may at least partially encapsulate the integrated device 102, the integrated device 104a, the integrated device 104b, the integrated device 106a, the integrated device 106b, the integrated device 108a and the integrated device 108b, the plurality of wire bonds 1020, the plurality of wire bonds 1060, the plurality of post interconnects 1040 and/or the plurality of post interconnects 1080. The encapsulation layer 1009 may include a mold, a resin, an epoxy and/or a filler. The encapsulation layer 1009 may be provided by using a compression and transfer molding process, a sheet molding process, or a liquid molding process. The encapsulation layer 1009 may be over molded. In some implementations, a planarization process of the encapsulation layer 1009 may be performed. A portion of the encapsulation layer 1009 may be removed and/or grinded off.

The method couples (at 1325) a second carrier and a second release layer. Stage 10 of FIG. 12D, illustrates and describes an example of a state after a second carrier 1220 is coupled to the encapsulation layer 1009 through a release layer 1230. The release layer 1230 may be an adhesive. The second carrier 1220 may be similar to the carrier 1200. The second carrier 1220 may include a similar material and/or a different material from the carrier 1200.

The method detaches (at 1330) the first carrier and the first release layer. Stage 11 of FIG. 12D, illustrates and describes an example of a state after the carrier 1200 and the release layer 1210 are detached from the metallization portion 1002.

The method forms (at 1335) a plurality of pillar interconnects and a plurality of solder interconnects. Stage 12 of FIG. 12E, illustrates and describes an example of a state after a plurality of pillar interconnects 1025 are formed. The plurality of pillar interconnects 1025 may be formed and coupled to the plurality of metallization interconnects 1022 of the metallization portion 1002. A plating process may be used to form the plurality of pillar interconnects 1025. Stage 12 also illustrates a state after a plurality of solder interconnects 1090 are coupled to the plurality of pillar interconnects 1025. A pasting process may be used to couple the plurality of solder interconnects 1090 to the plurality of pillar interconnects 1025.

The method detaches (at 1340) the second carrier and the second release layer. Stage 13 of FIG. 12E, illustrates and describes an example of a state after the second carrier 1220 and the release layer 1230 are detached from the encapsulation layer 1009. Stage 13 may illustrate an example of the package 1000.

### Exemplary Sequence for Fabricating a Metallization Portion

In some implementations, fabricating a substrate includes several processes. FIGS. 14A-14B illustrate an exemplary sequence for providing or fabricating a metallization portion. In some implementations, the sequence of FIGS. 14A-14B may be used to provide or fabricate the metallization portion 402. However, the process of FIGS. 14A-14B may be used to fabricate any of the metallization portions (e.g., 402, 702, 1002) described in the disclosure.

It should be noted that the sequence of FIGS. 14A-14B may combine one or more stages in order to simplify and/or clarify the sequence for providing or fabricating a metallization portion. In some implementations, the order of the processes may be changed or modified. In some implementations, one or more of processes may be replaced or substituted without departing from the scope of the disclosure.

Stage 1, as shown in FIG. 14A, illustrates a state after a carrier 1400 is provided. A seed layer 1401 may be located over the carrier 1400. The carrier 1400 may be replaced with other components and/or materials.

Stage 2 illustrates a state after a plurality of interconnects 1412 are formed. The interconnects 1412 may be located over the seed layer 1401. A lithography process, a plating process, a strip process and/or an etching process may be used to form the plurality of interconnects 1412. The interconnects 1412 may represent at least some of the interconnects from the plurality of metallization interconnects 123.

Stage 3 illustrates a state after a dielectric layer 1410 is formed over the carrier 1400, the seed layer 1401 and the plurality of interconnects 1412. A deposition and/or lamination process may be used to form the dielectric layer 1410. The dielectric layer 1410 may include prepreg and/or polyimide. The dielectric layer 1410 may include a photo-imageable dielectric. However, different implementations may use different materials for the dielectric layer.

Stage 4 illustrates a state after a plurality of cavities 1413 is formed in the dielectric layer 1410. The plurality of cavities 1413 may be formed using an etching process (e.g., photo etching process), a laser process, an exposure process and/or a development process.

Stage 5 illustrates a state after interconnects 1422 are formed in and over the dielectric layer 1410, including in and over the plurality of cavities 1413. For example, a via, pad and/or traces may be formed. A lithography process, a plating process, a strip process and/or an etching process may be used to form the interconnects.

Stage 6, as shown in FIG. 14B, illustrates a state after a dielectric layer 1420 is formed over the dielectric layer 1410 and the plurality of interconnects 1422. A deposition and/or lamination process may be used to form the dielectric layer 1420. The dielectric layer 1420 may include prepreg and/or polyimide. The dielectric layer 1420 may include a photo-imageable dielectric. However, different implementations may use different materials for the dielectric layer.

Stage 7, illustrates a state after a plurality of cavities 1423 is formed in the dielectric layer 1440. The dielectric layer 1440 may represent the dielectric layer 1410 and/or the dielectric layer 1420. The plurality of cavities 1423 may be formed using an etching process (e.g., photo etching process), a laser process, an exposure process and/or a development process.

Stage 8 illustrates a state after interconnects 1432 are formed in and over the dielectric layer 1440, including in and over the plurality of cavities 1423. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Metallization Portion

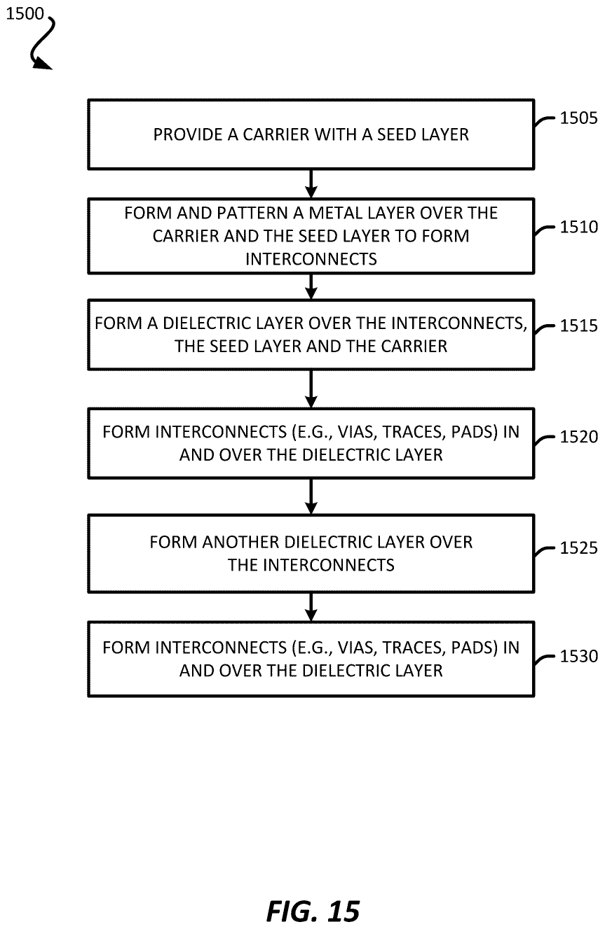

In some implementations, fabricating a substrate includes several processes. FIG. 15 illustrates an exemplary flow diagram of a method 1500 for providing or fabricating a metallization portion. In some implementations, the method 1500 of FIG. 15 may be used to provide or fabricate the metallization portion(s) of the disclosure. For example, the method 1500 of FIG. 15 may be used to fabricate the metallization portion 402, the metallization portion 702 and/or the metallization portion 1002.

It should be noted that the method 1500 of FIG. 15 may combine one or more processes in order to simplify and/or clarify the method for providing or fabricating a metallization portion. In some implementations, the order of the processes may be changed or modified.

The method provides (at 1505) a carrier with a seed layer. Stage 1 of FIG. 14A, illustrates and describes an example of a state after a carrier 1400 is provided. A seed layer 1401 may be located over the carrier 1400. The carrier 1400 may be replaced with other components and/or materials.

The method forms and patterns (at 1510) a plurality of interconnects. Stage 2 of FIG. 14A, illustrates and describes an example of a state after a plurality of interconnects 1412 are formed. The interconnects 1412 may be located over the seed layer 1401. A lithography process, a plating process, a strip process and/or an etching process may be used to form the plurality of interconnects 1412. The interconnects 1412 may represent at least some of the interconnects from the plurality of metallization interconnects 123.

The method forms (at 1510) a dielectric layer. Stage 3 of FIG. 14A, illustrates and describes an example of a state after a dielectric layer 1410 is formed over the carrier 1400, the seed layer 1401 and the plurality of interconnects 1412. A deposition and/or lamination process may be used to form the dielectric layer 1410. The dielectric layer 1410 may include prepreg and/or polyimide. The dielectric layer 1410 may include a photo-imageable dielectric. However, different implementations may use different materials for the dielectric layer.

The method forms (at 1520) a plurality of interconnects. Forming a plurality of interconnects may including forming a plurality of cavities in a dielectric layer and a performing a plating process. Stage 4 of FIG. 14A, illustrates and describes an example of a state after a plurality of cavities 1413 is formed in the dielectric layer 1410. The plurality of cavities 1413 may be formed using an etching process (e.g., photo etching process), a laser process, an exposure process and/or a development process.

Stage 5 of FIG. 14A, illustrates and describes an example of a state after interconnects 1422 are formed in and over the dielectric layer 1410, including in and over the plurality of cavities 1413. For example, a via, pad and/or traces may be formed. A lithography process, a plating process, a strip process and/or an etching process may be used to form the interconnects.

The method forms (at 1525) another dielectric layer. Stage 6 of FIG. 14B, illustrates and describes an example of a state after a dielectric layer 1420 is formed over the dielectric layer 1410 and the plurality of interconnects 1422. A deposition and/or lamination process may be used to form the dielectric layer 1420. The dielectric layer 1420 may include prepreg and/or polyimide. The dielectric layer 1420 may include a photo-imageable dielectric. However, different implementations may use different materials for the dielectric layer.

The method forms (at 1530) a plurality of interconnects. Forming a plurality of interconnects may including forming a plurality of cavities in a dielectric layer and a performing a plating process. Stage 7 of FIG. 14B, illustrates and describes an example of a state after a plurality of cavities 1423 is formed in the dielectric layer 1440. The dielectric layer 1440 may represent the dielectric layer 1410 and/or the dielectric layer 1420. The plurality of cavities 1423 may be formed using an etching process (e.g., photo etching process), a laser process, an exposure process and/or a development process.

Stage 8 of FIG. 14B, illustrates and describes an example of a state after interconnects 1432 are formed in and over the dielectric layer 1440, including in and over the plurality of cavities 1423. For example, a via, pad and/or traces may be formed. A lithography process, a plating process, a strip process and/or an etching process may be used to form the interconnects.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

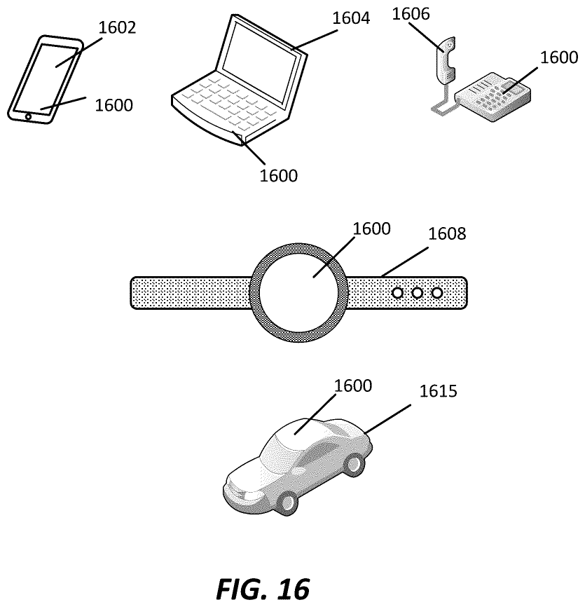

FIG. 16 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1602, a laptop computer device 1604, a fixed location terminal device 1606, a wearable device 1608, or automotive vehicle 1610 may include a device 1600 as described herein. The device 1600 may be, for example, any of the devices and/or integrated circuit (IC) packages described herein. The devices 1602, 1604, 1606 and 1608 and the vehicle 1610 illustrated in FIG. 16 are merely exemplary. Other electronic devices may also feature the device 1600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-4, 5A-5D, 6-7, 8A-8D, 9-11, 12A-12E, 13, 14A-14B, and 15-16 may be rearranged and/or combined into a single component, process, feature or function or embodied in several components, processes, or functions. Additional elements, components, processes, and/or functions may also be added without departing from the disclosure. It should also be noted FIGS. 1-4, 5A-5D, 6-7, 8A-8D, 9-11, 12A-12E, 13, 14A-14B, and 15-16 and its corresponding description in the present disclosure is not limited to dies and/or ICs. In some implementations, FIGS. 1-4, 5A-5D, 6-7, 8A-8D, 9-11, 12A-12E, 13, 14A-14B, and 15-16 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first integrated device; a second integrated device coupled to the first integrated device through an adhesive; a first plurality of wire bonds coupled to the first integrated device; a second plurality of wire bonds coupled to the second integrated device; an encapsulation layer at least partially encapsulating the first integrated device, the second integrated device, the first plurality of wire bonds and the second plurality of wire bonds; and a plurality of pillar interconnects.

Aspect 2: The package of aspect 1, wherein the plurality of pillar interconnects are coupled to and touching the first plurality of wire bonds and the second plurality of wire bonds.

Aspect 3: The package of aspects 1 through 2, further comprising a metallization portion coupled to the first plurality of wire bonds and the second plurality of wire bonds.

Aspect 4: The package of aspect 3, wherein the plurality of pillar interconnects are coupled to the metallization portion, and wherein the metallization portion is located between the plurality of pillar interconnects and the first plurality of wire bonds.

Aspect 5: The package of aspects 1 through 4, wherein the first plurality of wire bonds include a first wire bond that extends (i) from the first integrated device to a first side of the encapsulation layer, and (ii) from the first side of the encapsulation layer to a second side of the encapsulation layer, wherein the second side of the encapsulation layer is opposite to the first side of the encapsulation layer.

Aspect 6: The package of aspect 5, wherein the second plurality of wire bonds include a second wire bond that extends (i) from the second integrated device to the first side of the encapsulation layer, and (ii) from the first side of the encapsulation layer to the second side of the encapsulation layer.

Aspect 7: The package of aspect 5, wherein the second plurality of wire bonds include a second wire bond that extends from the second integrated device to the second side of the encapsulation layer.

Aspect 8: The package of aspects 1 through 7, wherein the first plurality of wire bonds include a first wire bond that is free of any electrical connection with any integrated device.

Aspect 9: The package of aspects 1 through 8, wherein the adhesive include a die attach film (DAF).

Aspect 10: The package of aspects 1 through 9, further comprising a third integrated device coupled to the second integrated device through a second adhesive; and a third plurality of wire bonds coupled to the third integrated device, wherein the third plurality of wire bonds include a wire bond that extends (i) from the third integrated device to a first side of the encapsulation layer, and (ii) from the first side of the encapsulation layer to a second side of the encapsulation layer, wherein the second side of the encapsulation layer is opposite to the first side of the encapsulation layer.

Aspect 11: A package comprising a first integrated device; a second integrated device coupled to the first integrated device through an adhesive; a first plurality of wire bonds coupled to the first integrated device; a second plurality of wire bonds coupled to the second integrated device; an encapsulation layer at least partially encapsulating the first integrated device, the second integrated device, the first plurality of wire bonds and the second plurality of wire bonds; a metallization portion coupled to the first plurality of wire bonds and the second plurality of wire bonds; and a plurality of pillar interconnects coupled to the metallization portion.

Aspect 12: The package of aspect 11, wherein the metallization portion comprises at least one dielectric layer; and a plurality of metallization interconnects, wherein the plurality of metallization interconnects are coupled to the first plurality of wire bonds, the second plurality of wire bonds and the plurality of pillar interconnects.

Aspect 13: The package of aspects 11 through 13, wherein the first integrated device and the second integrated device are part of a stack of integrated device.

Aspect 14: A package comprising a metallization portion; a first integrated device coupled to the metallization portion through an adhesive; a first plurality of wire bonds coupled to the first integrated device and the metallization portion; a second integrated device coupled to the metallization portion through a first plurality of pillar interconnects and a first plurality of solder interconnects, wherein the second integrated device vertically overlaps with the first integrated device; and an encapsulation layer at least partially encapsulating the first integrated device and the second integrated device.

Aspect 15: The package of aspect 14, further comprising a third integrated device coupled to the second integrated device through a second adhesive, wherein the third integrated device vertically overlaps with the second integrated device; and a second plurality of wire bonds coupled to the third integrated device and the metallization portion.

Aspect 16: The package of aspect 15, further comprising a fourth integrated device coupled to the metallization portion through a second plurality of pillar interconnects and a second plurality of solder interconnects, wherein the fourth integrated device vertically overlaps with the third integrated device.

Aspect 17: The package of aspect 16, wherein a front side of the first integrated device faces in a direction away from the metallization portion, wherein a front side of the second integrated device faces in a direction towards the metallization portion, wherein a front side of the third integrated device faces in a direction away from the metallization portion, and wherein a front side of the fourth integrated device faces in a direction towards the metallization portion.

Aspect 18: The package of aspects 16 through 17, further comprising a non-conducting material layer between the second integrated device and the metallization portion.

Aspect 19: The package of aspects 16 through 18, wherein the encapsulation layer at least partially encapsulates the first integrated device, the second integrated device, the third integrated device, the fourth integrated device the first plurality of wire bonds and the second plurality of wire bonds.

Aspect 20: The package of aspects 16 through 19, wherein the first integrated device, the second integrated device, the third integrated device, the fourth integrated device are each a memory die.

Aspect 21: A device comprising aspects 1 through 20, wherein the device is from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first integrated device;
a second integrated device coupled to the first integrated device through an adhesive;
a first plurality of wire bonds coupled to the first integrated device;
a second plurality of wire bonds coupled to the second integrated device;
an encapsulation layer at least partially encapsulating the first integrated device, the second integrated device, the first plurality of wire bonds and the second plurality of wire bonds; and
a plurality of pillar interconnects.

2. The package of claim 1, wherein the plurality of pillar interconnects are coupled to and touching the first plurality of wire bonds and the second plurality of wire bonds.

3. The package of claim 1, further comprising a metallization portion coupled to the first plurality of wire bonds and the second plurality of wire bonds.

4. The package of claim 3,
wherein the plurality of pillar interconnects are coupled to the metallization portion, and
wherein the metallization portion is located between the plurality of pillar interconnects and the first plurality of wire bonds.

5. The package of claim 1, wherein the first plurality of wire bonds include a first wire bond that extends (i) from the first integrated device to a first side of the encapsulation layer, and (ii) from the first side of the encapsulation layer to a second side of the encapsulation layer, wherein the second side of the encapsulation layer is opposite to the first side of the encapsulation layer.

6. The package of claim 5, wherein the second plurality of wire bonds include a second wire bond that extends (i) from the second integrated device to the first side of the encapsulation layer, and (ii) from the first side of the encapsulation layer to the second side of the encapsulation layer.

7. The package of claim 5, wherein the second plurality of wire bonds include a second wire bond that extends from the second integrated device to the second side of the encapsulation layer.

8. The package of claim 1, wherein the first plurality of wire bonds include a first wire bond that is free of any electrical connection with any integrated device.

9. The package of claim 1, wherein the adhesive include a die attach film (DAF).

10. The package of claim 1, further comprising:
a third integrated device coupled to the second integrated device through a second adhesive; and
a third plurality of wire bonds coupled to the third integrated device, wherein the third plurality of wire bonds include a wire bond that extends (i) from the third integrated device to a first side of the encapsulation layer, and (ii) from the first side of the encapsulation layer to a second side of the encapsulation layer, wherein the second side of the encapsulation layer is opposite to the first side of the encapsulation layer.

11. A package comprising:
a first integrated device;
a second integrated device coupled to the first integrated device through an adhesive;
a first plurality of wire bonds coupled to the first integrated device;
a second plurality of wire bonds coupled to the second integrated device;
an encapsulation layer at least partially encapsulating the first integrated device, the second integrated device, the first plurality of wire bonds and the second plurality of wire bonds;
a metallization portion coupled to the first plurality of wire bonds and the second plurality of wire bonds; and
a plurality of pillar interconnects coupled to the metallization portion.

12. The package of claim 11, wherein the metallization portion comprises:
at least one dielectric layer; and
a plurality of metallization interconnects, wherein the plurality of metallization interconnects are coupled to the first plurality of wire bonds, the second plurality of wire bonds and the plurality of pillar interconnects.

13. The package of claim 11, wherein the first integrated device and the second integrated device are part of a stack of integrated device.

14. A package comprising:
a metallization portion;
a first integrated device coupled to the metallization portion through an adhesive;
a first plurality of wire bonds coupled to the first integrated device and the metallization portion;
a second integrated device coupled to the metallization portion through a first plurality of pillar interconnects and a first plurality of solder interconnects, wherein the second integrated device vertically overlaps with the first integrated device; and
an encapsulation layer at least partially encapsulating the first integrated device and the second integrated device.

15. The package of claim 14, further comprising:
a third integrated device coupled to the second integrated device through a second adhesive, wherein the third integrated device vertically overlaps with the second integrated device; and
a second plurality of wire bonds coupled to the third integrated device and the metallization portion.

16. The package of claim 15, further comprising a fourth integrated device coupled to the metallization portion through a second plurality of pillar interconnects and a second plurality of solder interconnects, wherein the fourth integrated device vertically overlaps with the third integrated device.

17. The package of claim 16,
wherein a front side of the first integrated device faces in a direction away from the metallization portion,
wherein a front side of the second integrated device faces in a direction towards the metallization portion,
wherein a front side of the third integrated device faces in a direction away from the metallization portion, and
wherein a front side of the fourth integrated device faces in a direction towards the metallization portion.

18. The package of claim 16, further comprising a non-conducting material layer between the second integrated device and the metallization portion.

19. The package of claim 16, wherein the encapsulation layer at least partially encapsulates the first integrated device, the second integrated device, the third integrated device, the fourth integrated device the first plurality of wire bonds and the second plurality of wire bonds.

20. The package of claim 16, wherein the first integrated device, the second integrated device, the third integrated device, the fourth integrated device are each a memory die.
